(19) United States
(12) Patent Application Publication
(10) Pub. No.: US 2023/0143126 A1
(43) Pub. Date: May 11, 2023

(54) Organic Light Emitting Display Device

(71) Applicant: LG Display Co., Ltd., Seoul (KR)

(72) Inventors: Deu-Ho Yeon, Paju-si (KR); Kum-Mi Oh, Paju-si (KR); Sun-Wook Ko, Paju-si (KR)

(21) Appl. No.: 17/980,181

(22) Filed: Nov. 3, 2022

(30) Foreign Application Priority Data
Nov. 11, 2021 (KR) 10-2021-0154766

(51) Int. Cl. H01L 27/32; H01L 51/56

(52) U.S. Cl. CPC H01L 27/3262; H01L 27/3265; H01L 27/3272; H01L 51/56; H01L 2227/323; H01L 27/1225

(57) ABSTRACT

An organic light emitting display device comprises a substrate including a display area and a non-display area, a driving thin film transistor and at least one switching thin film transistor in the display area, and an organic light device in the display area, wherein the driving thin film transistor and the switching thin film transistor include respectively an oxide semiconductor layer, and wherein a surface treating layer including a pattern of protrusions is on an upper surface of the oxide semiconductor layer of the driving thin film transistor.

### CROSS-REFERENCE TO RELATED APPLICATION

This application claims priority to and the benefit of Republic of Korea Patent Application No. 10-2021-0154766, filed on Nov. 11, 2021, which is hereby incorporated by reference in its entirety.

### BACKGROUND

### 1. Technical Field

The present disclosure relates to an organic light emitting display device, and in particular the organic light emitting display device capable of good grayscale expression and a fast on-off rate by adjusting a S-factor of a specific thin film transistor among a plurality of thin film transistors.

### 2. Discussion of the Related Art

As multimedia develops, the importance of flat panel display is increasing. As such a flat panel display device, a flat panel display device such as a liquid crystal display device, a plasma display device, and an organic light emitting display device has been commercialized. Among these flat panel display devices, the organic light emitting display device is currently widely used in because of a high response speed, high luminance and good viewing angle.

In the organic light emitting display device, a plurality of pixels are arranged in a matrix shape, and an organic light emitting device and a thin film transistor are disposed in each pixel. The thin film transistor includes a plurality of thin film transistors such as a driving TFT for supplying a driving current to operate the organic light emitting diode and a switching thin film transistor for supplying a gate signal to the driving thin film transistor.

Since the plurality of thin film transistors of the organic light emitting display device perform different functions, electrical characteristics according to different functions must also be different from each other. In order to vary the electrical characteristics of the plurality of thin film transistors disposed in the pixel, the plurality of thin film transistors having different structures must be formed in the pixel or the plurality of thin film transistors made of different semiconductor materials must be formed in the pixel. However, in this case, there is a problem in that the manufacturing process is complicated and the manufacturing cost is increased.

### SUMMARY

Accordingly, embodiments of the present disclosure are directed to a display device that substantially obviates one or more of the problems due to limitations and disadvantages of the related art.

An object of the present disclosure is to provide an organic light emitting display device that enables rich grayscale expression and fast switching.

To achieve the object the organic light emitting display device according to the present disclosure comprises a substrate including a display area and a non-display area; a driving thin film transistor and a switching thin film transistor in the display area; and an organic light device in the display area, the organic light emitting device electrically connected to the driving thin film transistor, wherein the driving thin film transistor includes a first oxide semiconductor layer and the switching thin film transistor includes a second oxide semiconductor layer, and wherein a surface treating layer including a pattern of protrusions is on a surface of the first oxide semiconductor layer of the driving thin film transistor and the second oxide semiconductor layer of the switching thin film transistor lacks the surface treating layer on a surface of the second oxide semiconductor layer.

In one embodiment, a display device comprises: a substrate including a display area; a first transistor in the display area, the first transistor including a first semiconductor layer with a pattern of protrusions on at least a portion of a surface of the first semiconductor layer; a second transistor in the display area, the second transistor including a second semiconductor layer that is made of a same material as the first semiconductor layer; and a light emitting device in the display area, the light emitting device electrically connected to the first transistor, wherein the second semiconductor layer lacks the pattern of protrusions on any surface of the second semiconductor layer.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a schematic block diagram of an organic light emitting display device according to one embodiment of the present disclosure.

FIG. 2 is the schematic block diagram of a sub-pixel of the organic light emitting display device according to one embodiment of the present disclosure.

FIG. 3 is a circuit diagram of the sub-pixel of the organic light emitting display device according to one embodiment of the present disclosure.

FIG. 4 is a cross-sectional view of the organic light emitting display device according to a first embodiment of the present disclosure.

FIGS. 5A and 5B are views illustrating respectively an enlarged picture of a surface and a S-factor of the switching thin film transistor and the driving thin film transistor according to the first embodiment of the present disclosure.

FIG. 6 is a partially enlarged cross-sectional view of the driving thin film transistor of then organic light emitting display device according to the first embodiment of the present disclosure.

FIGS. 7A to 7D are enlarged cross-sectional views illustrating another structure of a surface treating layer of the organic light emitting display device according to the first embodiment of the present disclosure.

FIG. 8 is the cross-sectional view illustrating the structure of the organic light emitting display device according to a second embodiment of the present disclosure.

FIGS. 9A to 9D are diagrams illustrating a method of manufacturing the organic light emitting display device according to the first and second embodiments of the present disclosure.

FIGS. 10A to 10D are views illustrating an example of the method of forming the first and second semiconductor layers of the organic light emitting display device according to the first embodiment of the present invention.

FIGS. 11A to 11C are views illustrating another example of the method of forming the first and second semiconductor layers of the organic light emitting display device according to the first embodiment of the present disclosure.

FIG. 12 is a cross-sectional view illustrating the structure of the organic light emitting display device according to a third embodiment of the present disclosure.

FIGS. 13A to 13D are views illustrating the method of forming the semiconductor layer of the organic light emitting display device according to the third embodiment of the present disclosure.

FIG. 14 is a cross-sectional view illustrating the structure of the organic light emitting display device according to a fourth embodiment of the present disclosure.

FIG. 15 is an enlarged cross-sectional view of the driving thin film transistor according to the fourth embodiment of the present disclosure.

FIG. 16 is an enlarged view of area A of FIG. 14 according to the fourth embodiment of the present disclosure.

FIGS. 17A-17H are diagrams illustrating the method of manufacturing the organic light emitting display device according to the fourth embodiment of the present disclosure.

### DETAILED DESCRIPTION

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains, and the present disclosure is defined only by the scope of the appended claims.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is not used, one or more other parts may be located between the two parts.

In describing a temporal relationship, for example, when a temporal predecessor relationship is described as being “after,” “subsequent,” “next to,” “prior to,” or the like, unless “immediately” or “directly” is not used, cases that are not continuous may also be included.

Although the terms first, second, and the like are used to describe various components, these components are not substantially limited by these terms. These terms are used only to distinguish one component from another component. Therefore, a first component described below may substantially be a second component within the technical spirit of the present disclosure.

In describing components of the specification, the terms first, second, A, B, (a), (b), and the like can be used. These terms are intended to distinguish one component from other components, but the nature, sequence, order, or number of the components is not limited by those terms. When components are disclosed as being “connected,” “coupled,” or “in contact” with other components, the components can be directly connected or in contact with the other components, but it should be understood that other component(s) could be “interposed” between the components and the other components or could be “connected,” “coupled,” or “contacted” therebetween.

Hereinafter, the present invention will be described in detail accompanying drawings.

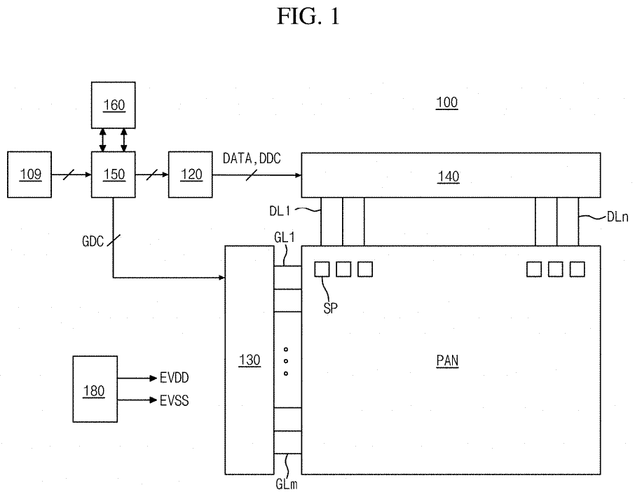

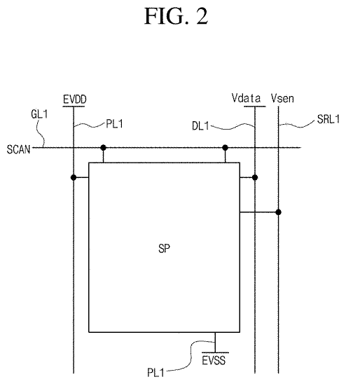

FIG. 1 is the schematic block diagram of an organic light emitting display device according to one embodiment and FIG. 2 is the schematic block diagram of the sub-pixel of the organic light emitting display device according to one embodiment.

As shown in FIG. 1, the organic light emitting display device 100 includes an image processing unit 109 (e.g., a circuit), a deterioration compensating unit 150 (e.g., a circuit), a memory 160, a timing controlling unit 120 (e.g., a circuit), a gate driving unit 130 (e.g., a circuit), a data driving unit 140 (e.g., a circuit), a power supplying unit 180 (e.g., a circuit), and a display panel PAN.

The image processing unit 109 outputs an image data supplied from outside and a driving signal for driving various devices. For example, the driving signal from the image processing unit 109 can include a data enable signal, a vertical synchronizing signal, a horizontal synchronizing signal, and a clock signal.

The image data and the driving signal are supplied to the timing controlling unit 120 from the image processing unit 109. The timing controlling unit 120 writes and outputs gate timing controlling signal GDC for controlling the driving timing of the gate driving unit 130 and data timing controlling signal DDC for controlling the driving timing of the data driving unit 140 based on the driving signal from the image processing unit 109.

The gate driving unit 130 outputs the scan signal to the display panel PAN in response to the gate timing control signal GDC supplied from the timing controlling unit 120. The gate driving unit 130 outputs the scan signal through a plurality of gate lines GL1 to GLm. In this case, the gate driving unit 130 may be formed in the form of an integrated circuit (IC), but is not limited thereto. In particular, the gate driving unit 130 may have a GIP (Gate In Panel) structure formed by directly depositing thin film transistors on a substrate inside the organic light emitting display device 100. The GIP may include a plurality of circuits such as a shift register and a level shifter.

The data driver 140 outputs the data voltage to the display panel PAN in response to the data timing control signal DDC input from the timing controlling unit 120. The data driving unit 140 samples and latches the digital data signal DATA supplied from the timing controlling unit 120 to convert it into the analog data voltage based on the gamma voltage. The data driving unit 140 outputs the data voltage through the plurality of data lines DL1 to DLn. In this case, the data driving 140 may be mounted on the upper surface of the display panel PAN in the form of an integrated circuit (IC) or may be formed by depositing various patterns and layers directly on the display panel PAN, but is limited thereto.

The power supplying unit 180 outputs a high potential driving voltage EVDD and a low potential driving voltage EVSS etc. to supply these to the display panel PAN. The high potential driving voltage EVDD and the low potential driving voltage EVSS is supplied to the display panel PAN through the power line. In this time, the voltage from the power supplying unit 180 are applied to the data driving unit 140 or the gate driving unit 130 to drive thereto.

The display panel PAN displays the image based on the data voltage from the data driving unit 140, the scan signal from the gage driving unit 130, and the power from the power supplying unit 180.

The display panel PAN includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

As shown in FIG. 2, one sub-pixel SP may be connected to the gate line GL1, the data line DL1, the sensing voltage readout line SRL1, and the power line PL1. The number of transistors and capacitors and the driving method of the sub-pixel SP are determined according to the circuit configuration.

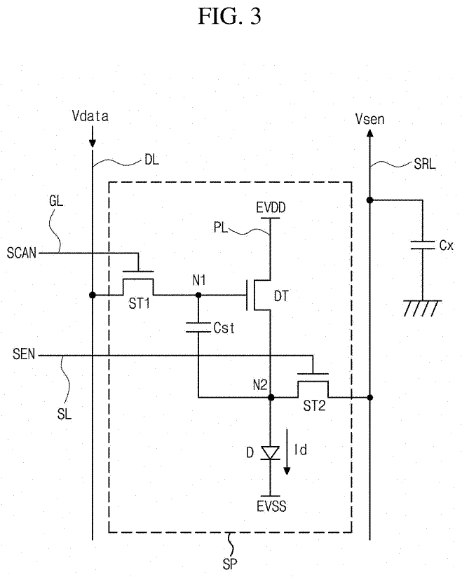

FIG. 3 is the circuit diagram illustrating the sub-pixel SP of the organic light emitting display device 100 according to one embodiment of the present disclosure.

As shown in FIG. 3, the organic light emitting display device 100 according to the present disclosure includes the gate line GL, the data line DL, the power line PL, and the sensing line SL crossing each other to define the sub-pixel SP. A driving thin film transistor DT, an organic light emitting device D, a storage capacitor Cst, a first switching thin film transistor ST, and a second switching thin film transistor ST2 are disposed in the sub-pixel SP.

The organic light emitting device D includes an anode electrode connected to a second node N2, a cathode electrode connected to an input terminal of the low potential driving voltage EVSS, and an organic light emitting layer disposed between the anode electrode and the cathode electrode.

The driving thin film transistor DT controls the current Id flowing through the organic light emitting diode D according to the gate-source voltage Vgs. The driving thin film transistor DT includes a gate electrode connected to a first node N1, a drain electrode connected to the power line PL to provide the high potential driving voltage EVDD, and a source electrode connected to the second node N2.

The storage capacity Cst is connected between the first node N1 and the second node N2.

When the display panel PAN is operating, the first switch thin film transistor ST1 applies the data voltage Vdata charged in the data line DL to the first node N1 in response to the gate signal SCAN to turn on the driving TFT DT. In this case, the first switch thin film transistor ST1 includes the gate electrode connected to the gate line GL to receive the scan signal SCAN, the drain electrode connected to the data line DL to receive the data voltage Vdata, and the source electrode connected to first node N1.

The second switching thin film transistor ST2 switches the current between the second node N2 and the sensing voltage readout line SRL in response to the sensing signal SEN to store the source voltage of the second node N2 in a sensing capacitor Cx of the readout line SRL. The second switching thin film transistor ST2 switches the current between the second node N2 and the sensing voltage readout line SRL in response to the sensing signal SEN when the display panel PAN is operating to reset the source voltage of the driving thin film transistor DT into the initial voltage Vpre. In this case, the gate electrode of the second switching thin film transistor ST2 is connected to the sensing line SL, the drain electrode is connected to the second node N2, and the source electrode is connected to the sensing voltage readout line SRL.

Meanwhile, in the figures, the organic light emitting display device having a 3T1C structure including three thin film transistors and one storage capacitor has been exemplified and described, but the organic light emitting display device of the present invention is not limited to this structure. The organic light emitting display device according to the present invention may be formed in the various structure such as b 4T1C, 5T1C, 6T1C, 7T1C, and 8T1C.

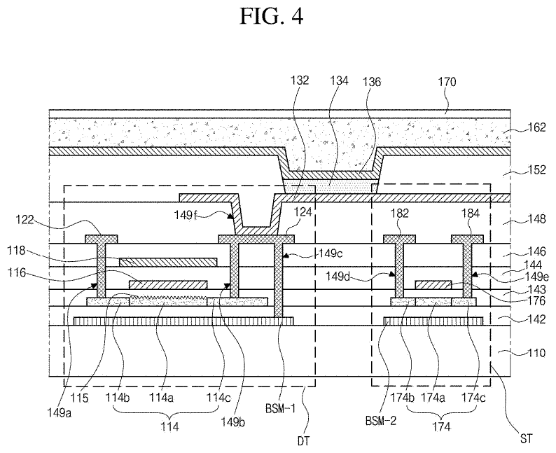

FIG. 4 is a cross-sectional view of the organic light emitting display device according to a first embodiment of the present disclosure.

As shown in FIG. 4, the driving thin film transistor DT and the switching thin film transistor ST are disposed on the first substrate 110. At this time, although only the driving thin film transistor DT and one switching thin film transistor ST are disclosed in the drawings, this is for convenience of description. A plurality of switching thin film transistors ST may be disposed on the first substrate 110.

The driving thin film transistor DT includes a first lower blocking metal layer BSM_1 disposed on the first substrate 110, a buffer layer 142 formed on the first substrate 110 to cover the first lower blocking metal layer BSM_1, a first semiconductor layer 114 disposed on the buffer layer 142, a gate insulating layer 143 deposited on the buffer layer 142 to cover the first semiconductor layer 114, a first gate electrode 116 on the gate insulating layer 143, an interlayer insulating layer 144 on the gate insulating layer 143 to cover the first gate electrode 116, a storage electrode 118 on the interlayer insulating layer 144, a passivation layer 146 on the interlayer insulating layer 144 to cover the storage electrode 118, and a first source electrode 122 and a first drain electrode 124 on the passivation layer 146.

The first substrate 110 may be made of a flexible plastic material. For example, polyimide (PI), polyethylene terephthalate (PET), polyethylene naphthalate (PEN), polycarbonate (PC), polyethersulfone (PES), polyarylate (PAR), polysulfone (PSF), and COC. (ciclic-olefin copolymer) may be used as the first substrate 110. However, the first substrate 110 of the present invention is not limited to such a flexible material, but may be formed of a hard transparent material such as glass.

The first lower blocking metal layer BSM_1 reduces a back-channel phenomenon caused by charges trapped from the first substrate 110 to prevent or at least reduce an afterimage or deterioration of transistor performance. The first lower blocking metal layer BSM_1 may be composed of a single layer or multi layers made of Ti, Mo or an alloy of Ti and Mo, but is not limited thereto.

The buffer layer 142 protects a thin film transistor formed in a subsequent process from impurities such as alkali ions leaking from the first substrate 110. In addition, the buffer layer 142 may block moisture that may penetrate from the outside. The buffer layer 142 may be a single layer made of silicon oxide (SiOx) or silicon nitride (SiNx) or a multilayer thereof.

The first semiconductor layer 114 may be formed of an oxide semiconductor such as indium gallium zinc oxide (IGZO). The first semiconductor layer 114 includes a first channel region 114a in a central region and a first source region 114b and a first drain region 114c that are doped layers on both sides of the first channel region 114a.

A surface treating layer 115 is formed on the upper surface of the first semiconductor layer 114. The surface treating layer 115 impart a roughness to the surface of the first semiconductor layer 114 by surface-treating the upper surface of the first semiconductor layer 114. In one embodiment, the roughness is caused by the formation of a pattern of protrusions at the surface of the first semiconductor layer 114. That is, the pattern of protrusions may repeat at a predetermined interval in one embodiment. Although described in detail later, an S-factor of the driving thin film transistor DT is increased by surface-treating the upper surface of the first semiconductor layer 114.

The surface treating layer 115 may be formed over the entire upper surface of the first semiconductor layer 114 or may be formed on the upper surface of the first channel region 114a but not first source region 114b and the first drain region 114c. That is, in one embodiment the plurality of protrusions of the surface treating layer 115 is on an entire surface of the first semiconductor layer 114 across the first source region 114b, the first channel region 114a, and the first drain region 114c. In another embodiment, the plurality of protrusions of the surface treating layer 115 is on a surface of the first channel region 114a of the first semiconductor layer 114, but is not on a surface of the first source region 114b and a surface of the first drain region 114c of the first semiconductor layer 114. Further, the surface treating layer 115 may be formed as a separate layer from the first semiconductor layer 114 or may be formed integrally with the first semiconductor layer 114 (i.e., the upper surface of the first semiconductor layer 114 may be treated).

The first gate electrode 116 may be formed of the single layer or the multi layers made of a metal such as Cr, Mo, Ta, Cu, Ti, Al, or an Al alloy, but is not limited thereto.

The interlayer insulating layer 144 may be formed of the single layer made of the inorganic material such as SiNx or SiOx or the multi layers thereof. The storage electrode 118 may be formed of the metal, but is not limited thereto.

The passivation layer 146 may be formed of the organic material such as photo acryl, but is not limited thereto. The passivation layer 146 may include a plurality of layers having the inorganic layer and the organic layer.

The first source electrode 122 and the first drain electrode 124 may be formed of the single layer or the multi layers made of a metal such as Cr, Mo, Ta, Cu, Ti, Al, or an Al alloy, but are not limited to

The first source electrode 122 and the first drain electrode 124 are in ohmic contact with the first source region 114b and the first drain region 114c of the first semiconductor layer 114, respectively, through a first contact hole 149a and a second contact hole 149b formed in the gate insulating layer 143, the interlayer insulating layer 144, and the passivation layer 146.

Further, the first drain electrode 124 is electrically connected to the first lower blocking layer BSM_1 through a third contact hole 149c formed in the gate insulating layer 143, the interlayer insulating layer, and the passivation layer. Thus, the first lower blocking layer BSM_1 is electrically connected to the first semiconductor layer 114 and the light emitting device as shown in FIG. 4.

The switching thin film transistor ST includes a second lower blocking layer BSM_2 on the first substrate 110, a second semiconductor layer 174, on the buffer layer 142, a second gate electrode 176 on the gate insulating layer, and a second electrode 182 and a drain electrode 184 on the passivation layer 146.

The second lower blocking metal layer BSM_2 may be formed of the single layer or the multi layers made of a metal such as Ti, Mo, or an alloy of Ti and Mo, but is not limited thereto. In this case, the second lower blocking metal layer BSM_2 may be formed of the same metal as the first lower blocking metal layer BSM_1, but may be formed of a different metal.

The second semiconductor layer 174 is made of the oxide semiconductor. The second semiconductor layer 174 includes a second channel region 174a in the central region and a second source region 174b and a second drain region 174c, which are doped layers, on both sides thereof. In this case, the second semiconductor layer 174 may be made of the same material as the first semiconductor layer 114, but is not limited thereto. The second semiconductor layer 174 may be made of the different material from the first semiconductor layer 114.

The second gate electrode 176 may be formed of the single layer or the multi layers made of the metal such as Cr, Mo, Ta, Cu, Ti, Al, or an Al alloy, but is not limited thereto. The second gate electrode 176 may be formed of the same metal as the first gate electrode 116, but is not limited thereto. The second gate electrode 176 may be formed of the different metal from the first gate electrode 116.

Each of the second source electrode 182 and the second drain electrode 184 may be formed of the single layer or the multi layers made of a metal such as Cr, Mo, Ta, Cu, Ti, Al, or an Al alloy, but these materials is not limited to. In this case, the second source electrode 182 and the second drain electrode 184 may be respectively made of the same metal as the first source electrode 122 and the first drain electrode 124, but are not limited thereto. The second source electrode 182 and the second drain electrode 184 may be respectively made of the different metal.

The second source electrode 182 and the second drain electrode 184 are respectively ohmic contacted to a second source region 174b and a second drain region 174c through a fourth contact hole 149d and a fifth contact hole 149e formed in the gate insulating layer 143, the interlayer insulating layer 144, and the passivation layer.

A planarization layer 148 is formed on the substrate 110 on which the driving thin film transistor DT and the switching thin film transistor ST are disposed. The planarization layer 148 may be formed of an organic material such as photo acrylic, but may also be formed of a plurality of layers including the inorganic layer and the organic layer. A sixth contact hole 249f is formed in the planarization layer 148.

A first electrode 132 electrically connected to the first drain electrode 124 of the driving transistor DT through the sixth contact hole 149f is formed on the planarization layer 148. The first electrode 132 is formed of the single layer or the multi layers made of a transparent conductive material such as an indium tin oxide (ITO) or an indium zinc oxide (IZO), or a thin metal through which visible light is transmitted in the case of bottom emission, but is not limited thereto. The first electrode 132 can be formed of single layer or the multi layers for reflecting a visible light in the case of top emission. The first electrode 132 is connected to the first drain electrode 124 of the driving transistor DT to receive an image signal from the outside.

A bank layer 152 is formed at a boundary between each sub-pixel SP on the planarization layer 148. The bank layer 152 is a barrier wall, and can prevent the light of a specific color output from the adjacent pixels from being mixed and output by partitioning each sub-pixel SP.

An organic light emitting layer 134 is formed on the first electrode 132 and on a portion of the inclined surface of the bank layer 152. The organic light emitting layer 134 may include an R organic light emitting layer to emit red light, a G organic light emitting layer to emit green light, and a B organic light emitting layer to emit blue light, which are formed in the R, G, and B pixels. Further, the organic light emitting layer 134 may include a W organic light emitting layer to emit white light.

The organic light emitting layer 134 may include a light emitting layer, an electron injecting layer and a hole injecting layer for respectively injecting electrons and holes into the light emitting layer, and an electron transporting layer and a hole transporting layer for respectively transporting the injected electrons and holes to the organic layer.

A second electrode 136 is formed on the organic light emitting layer 134. The second electrode 136 may be made of the metal such as Ca, Ba, Mg, Al, Ag, or an alloy thereof.

An encapsulating layer 162 is formed on the second electrode 136. The encapsulating layer 162 may be composed of the single layer made of the inorganic layer, may be composed of two layers of inorganic layer/organic layer, or may be composed of three layers of inorganic layer/organic layer/inorganic layer. The inorganic layer may be formed of the inorganic material such as SiNx and SiX, but is not limited thereto. Further, the organic layer may be formed of the organic material such as polyethylene terephthalate, polyethylene naphthalate, polycarbonate, polyimide, polyethylene sulfonate, polyoxymethylene, polyarylate, or a mixture thereof, but is not limited thereto.

A second substrate 170 is disposed on the encapsulation layer 162 and is attached by an adhesive layer (not shown). As the adhesive layer, any material may be used as long as it has good adhesion and good heat resistance and water resistance. In the present invention, a thermosetting resin such as an epoxy-based compound, an acrylate-based compound, or an acrylic rubber may be used. In addition, a photocurable resin may be used as the adhesive. In this case, the adhesive layer is cured by irradiating the adhesive layer with light such as ultraviolet rays.

The adhesive layer bonds the first substrate 110 and the second substrate 170 together, and may also serve as an encapsulation layer for blocking moisture into the display device.

The second substrate 170 is an encapsulation cap for encapsulating the electroluminescent display device. As the second substrate 170, a protective film such as a polystyrene (PS) film, a polyethylene (PE) film, a polyethylene naphthalate (PEN) film, or a polyimide (PI) film may be used, or glass may be used.

As described above, in the organic light emitting display device according to this embodiment of the present disclosure, both the driving thin film transistor DT and the switching thin film transistor ST disposed in the sub-pixel SP are oxide thin film transistors. At this time, although the driving thin film transistor DT and the switching thin film transistor ST have the same structure in the figures, they may have different structures.

On the other hand, in the organic light emitting display device of this embodiment of the present disclosure, the surface treating layer 115 is formed on the upper surface of the first semiconductor layer 114 of the driving thin film transistor DT, not on the upper surface of the second semiconductor layer 174 of the switching thin film transistor ST. The reason is to improve the driving efficiency of the organic light emitting display device by differentiating the electrical characteristics of the driving thin film transistor DT and the switching thin film transistor ST. Hereinafter, this will be described in detail.

The driving thin film transistor DT controls the current supplied to the organic light emitting device to emit light from the organic light emitting layer 134 to display an image. Therefore, the driving thin film transistor DT must have advantageous electrical characteristics for grayscale expression for sufficient grayscale expression of the image.

On the other hand, since the switching thin film transistor ST supplies a gate signal to the driving thin film transistor DT to display the image, the switching speed (i.e., on/off reaction speed) must be fast to implement the high quality image.

The best way to arrange the driving thin film transistor DT and the switching thin film transistor ST having different electrical characteristics in one pixel is to use semiconductor layers with different semiconductor materials to realize desired electrical characteristics. Or the structure of the driving thin film transistor DT and the switching old thin film transistor ST disposed in one pixel is different from each other to realize desired electrical characteristics.

However, in these cases, there is a problem that the process becomes complicated as well as expensive process equipment. In the present disclosure, the driving thin film transistor DT and the switching thin film transistor ST are formed in the same structure and one of the driving thin film transistor DT and the switching thin film transistor ST is surface treated to have different electrical characteristics.

That is, in the present disclosure, the surface treating layer 115 is formed on the upper surface of the first semiconductor layer 114 of the driving thin film transistor DT but is not formed on the upper surface of the second semiconductor layer 174 of the switching thin film transistor ST, so that the driving thin film transistor DT has the electric characteristic advantageous for the grayscale expression and the switching thin film transistor ST has the electric characteristic advantageous for the switching speed.

The thin film transistor using the oxide semiconductor not only has 10 times higher electrical mobility compared to the thin film transistor using the amorphous semiconductor, but also has a low process temperature, a simple process, and high uniformity. Therefore, the thin film transistor using the oxide semiconductor is advantageous for the large area display device.

In other words, since the on/off reaction speed of the thin film transistor using the oxide semiconductor is sufficiently fast, it can be applied to the switching thin film transistor (ST) without the separate surface treating. On the other hand, the driving thin film transistor DT may have electrical characteristics advantageous for grayscale expression by forming the surface treating layer 115 on the upper surface of the first semiconductor layer 114.

The surface treatment of the upper surface of the first semiconductor layer 114 increases the S-factor by imparting roughness to the first semiconductor layer 114. The S-factor, commonly referred to as the “sub-threshold slope,” represents the voltage required to increase the current tenfold. The S-factor is the inverse value of the slope of the graph of the voltage region lower than the threshold voltage in the graph (I-V curve) representing the characteristics of the drain current with respect to the gate voltage.

When the S-factor is small, since the slope of the characteristic graph (I-V) of the drain current with respect to the gate voltage is large (steep), the thin film transistor is turned on even by a small voltage, and thus the switching characteristics of the thin film transistor are improved. On the other hand, since the threshold voltage is reached in a short time, it is difficult to express sufficient gradation.

When the S-factor is large, since the slope of the characteristic graph (I-V) of the drain current with respect to the gate voltage is small, the on/off reaction speed of the thin film transistor is lowered. Therefore, although the switching characteristics of the thin film transistor are deteriorated, the threshold voltage is reached over a relatively long time, so that sufficient grayscale expression is possible.

In the present disclosure, the gradation expression of the image is enriched by increasing the S-factor of the driving thin film transistor (DT). At the same time, the S-factor of the switching thin film transistor ST is kept the same to maintain the fast switching characteristics of the oxide thin film transistor. Thus, the S-factor of the driving thin film transistor DT is greater than the S-factor of the switching thin film transistor ST in one embodiment.

In particular, in the present disclosure, the S-factor is increased by forming the surface treating layer 115 on the upper surface of the first semiconductor layer 114 of the driving thin film transistor DT to improve the driving characteristics of the driving thin film transistor DT.

The S-factor refers to the reaction rate of current to voltage. In case where the S-factor is low, the current increases rapidly when a voltage is applied. In case where the S-factor is high, the current increases slowly when a voltage is applied.

When the surface treating layer 115 is formed on the upper surface of the first semiconductor layer 114 of the driving thin film transistor DT, the roughness of the upper surface of the first semiconductor layer 114 is increased. As the roughness increases, distortion occurs at the interface of the upper surface of the first semiconductor layer 114. Since this distortion reduces the speed of current increase when the voltage is applied, the S-factor of the driving thin film transistor DT increases due to the increase of the roughness.

FIGS. 5A and 5B are views illustrating enlarged pictures and S-factors of the switching thin film transistor (ST) and the driving thin film transistor (DT) according to the first embodiment of the present disclosure.

As shown in FIG. 5A, since the surface treating layer is not formed on the upper surface of the second semiconductor layer 174 of the switching thin film transistor ST, the roughness of the upper surface of the second semiconductor layer 174 is relatively small (That is, the upper surface is flat and smooth), and the S-factor is 0.11 in this case.

As shown in FIG. 5B, since the surface treating layer 115 is formed on the upper surface of the first semiconductor layer 114 of the driving thin film transistor DT, the roughness of the upper surface of the first semiconductor layer 114 is relatively large (That is, the upper surface is uneven), and the S-factor is 0.16 in this case.

As described above, in the organic light emitting display device according to the first embodiment of the present disclosure, since the S-factor of the driving thin film transistor DT is greater than the S-factor of the switching thin film transistor ST, the grayscale expression of the driving thin film transistor DT may be enriched, and the switching thin film transistor ST can be switched quickly. As a result, it is possible to significantly improve the performance of the organic light emitting display device.

In addition, the first drain electrode 124 of the driving thin film transistor DT can be electrically connected to the first lower blocking metal layer BSM_1.

When the first lower blocking metal layer BSM_1 is formed on the first substrate 110 and the first drain electrode 124 is electrically connected to the first lower blocking metal layer BSM_1, the following additional effect can be obtained.

Since the first source region 114b and the first drain region 114c are doped with impurities, a parasitic capacitance C_{act} is generated inside the first semiconductor layer 114, a parasitic capacitance C_{g}, is generated between the first gate electrode 116 and the first semiconductor layer 114, and a parasitic capacitance C_{buf} is generated between the first lower blocking metal layer BSM_1 and the first semiconductor layer 114.

The first semiconductor layer 114 and the first lower blocking metal layer BSM_1 are electrically connected to each other via the first drain electrode 124, and thus the parasitic capacitance C_{act} and the parasitic capacitance C_{buf} are connected in parallel to each other, and the parasitic capacitance C_{act} and the parasitic capacitance C_{gi} are connected in series to each other. Further, when a gate voltage of V_{gat} is applied to the first gate electrode 116, the effective voltage V_{eff} that is actually applied to the first semiconductor layer 114 satisfies the following Equation 1, wherein Δ indicates variation of the corresponding voltage V_{eff} or V_{gat}.

$$Δ Veff = \frac{Cgi}{Cgi + Cbuf + Cact} * Δ Vgat \qquad [ Equation 1 ]$$

Accordingly, the effective voltage applied to the channel of the first semiconductor layer 114 is inversely proportional to the parasitic capacitance C_{buf}, and thus the effective voltage applied to the first semiconductor layer 114 may be adjusted by adjusting the parasitic capacitance C_{buf}.

That is, when the first lower blocking metal layer BSM_1 is disposed close to the first semiconductor layer 114 to increase the parasitic capacitance C_{buf}, the actual value of the current flowing through the first semiconductor layer 114 may be reduced.

The reduction in the effective value of the current flowing through the first semiconductor layer 114 means that the control range of the driving thin film transistor DT using the voltage V_{gat} that is actually applied to the first gate electrode 116 is widened.

Therefore, in the embodiment of the present disclosure illustrated in FIG. 4, the first lower blocking metal layer BSM_1 is disposed relatively close to the first semiconductor layer 114, thereby widening the range of grayscale values within which the driving thin-film transistor DT is capable of performing control. As a result, the light emitting element may be precisely controlled even at low grayscale values, and thus it may be possible to solve a problem of non-uniform luminance, which frequently occurs at low grayscale values. Thus, in the embodiment of the present disclosure, the parasitic capacitance C_{buf} may be increased compared to the parasitic capacitance C_{gi}, such that the control range of the driving thin film transistor DT may be improved in low grayscale values, and S-factor value of the driving thin film transistor DT may be increased additionally. For example, in the embodiment of the present disclosure, the parasitic capacitance C_{buf} may be larger than the parasitic capacitance C_{gi}.

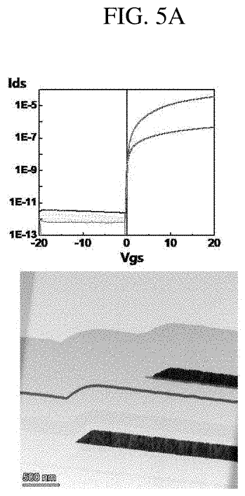

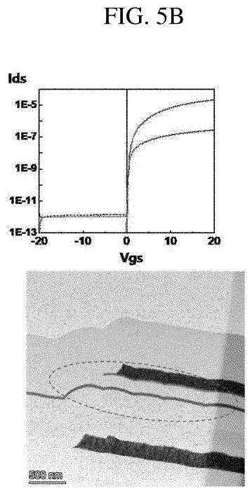

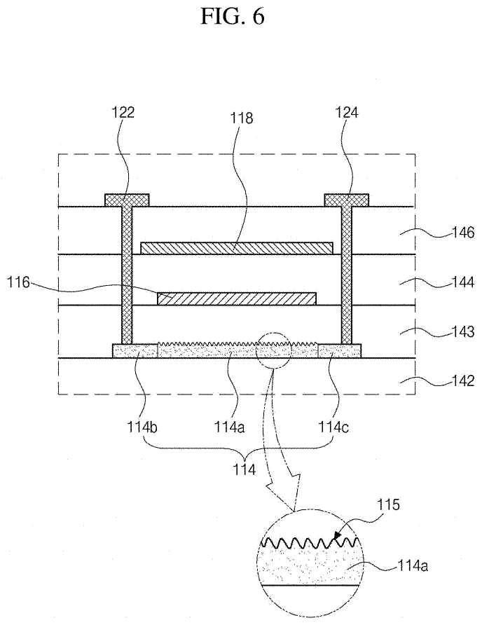

FIG. 6 is a partially enlarged cross-sectional view of the driving thin film transistor DT of the organic light emitting display device according to the first embodiment of the present disclosure, and is a view showing the surface treating layer 115 in detail.

As shown in FIG. 6, the surface treating layer 115 is formed on the upper surface of the first semiconductor layer 114. In this case, the surface treating layer 115 may be formed over the entire upper surface of the first semiconductor layer 114 or may be formed on the upper surface of the first channel 114a of the first semiconductor layer 114 but not the source and drain regions 114b and 114c.

The surface treating layer 115 provides roughness to the upper surface of the first semiconductor layer 114. In this case, the surface treating layer 115 may be formed integrally with the first semiconductor layer 114 or may be formed as a separate layer from the first semiconductor layer 114. For example, the surface treating layer 115 may be formed integrally with the first semiconductor layer 114 by surface treating the surface of the first semiconductor layer 114 itself, or may be formed by depositing the separate layer, of which is surface treated, on the first semiconductor layer 114. In one embodiment, the roughness is due to the pattern of protrusions on the upper surface of the first semiconductor layer 114. The pattern of protrusions on the upper surface of the first semiconductor layer 114 in one example.

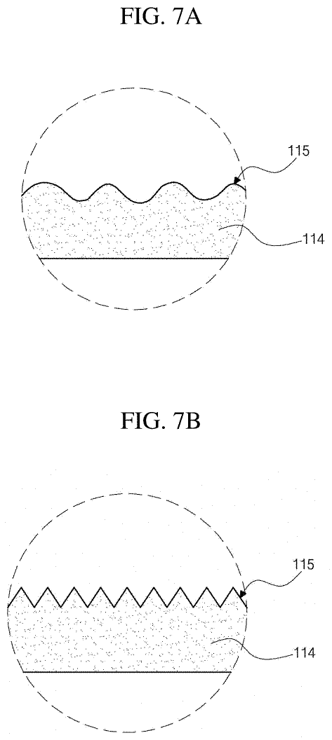

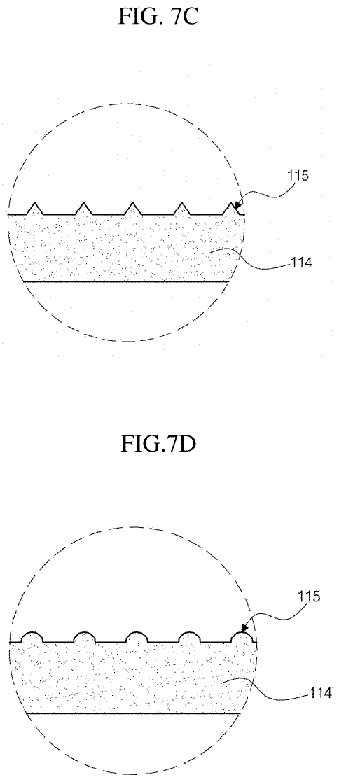

FIGS. 7A to 7D are enlarged cross-sectional views illustrating another structure of the surface treating layer 115 of the organic light emitting display device according to the present disclosure. At this time, although only the structure in which the surface treating layer 115 is formed integrally with the first semiconductor layer 114 is shown in the drawings, this structure may be applied even when the surface treating layer 115 is formed separately from the first semiconductor layer 114.

As shown in FIG. 7A, the surface treating layer 115 may be formed in a wavy shape pattern of concave and convex protrusions on the upper surface of the first semiconductor layer 114. In this case, the wave shape may be continuously formed over the entire surface of the first semiconductor layer 114 or may be formed discontinuously. Further, the wavy shape may be formed in the same size over the entire surface of the first semiconductor layer 114 or may be irregularly formed in different sizes.

As shown in FIG. 7B, the surface treating layer 115 may have a triangular shape pattern of protrusions on the upper surface of the first semiconductor layer 114. In this case, the triangular shape may be continuously formed over the entire surface of the first semiconductor layer 114 or may be formed discontinuously. Further, the triangular shape may be formed in the same size over the entire surface of the first semiconductor layer 114 or may be irregularly formed in different sizes.

As described above, the surface treating layer 115 is formed in various shapes such as the wavy shape or the triangular shape to increase the surface roughness of the first semiconductor layer 114 to increase the S-factor of the driving thin film transistor DT. Although not shown in the figures, the surface treating layer 115 may be formed in various shapes such as a micro-lens shape.

As shown in FIGS. 7C and 7D, the surface treating layer 115 may have a polygonal shape pattern of protrusions such as a triangular shape or a curved shape such as a semicircular shape. In this case, the polygonal shape protrusion and the curved shape protrusion may be formed continuously, but may be formed discontinuously by being spaced apart by a predetermined distance.

Since the polygonal shaped pattern of protrusions and the curved shaped pattern of protrusion are periodically arranged, the separation distance between the polygonal shapes and the curved shapes may be constant over the entire upper surface of the first semiconductor layer 114. Further, since the polygonal shape and the curved shape are non-periodically arranged, the distance between the polygonal shapes and the curved shapes may be irregular on the entire upper surface of the first semiconductor layer 114.

As described above, in the organic light emitting display device according to the first embodiment of the present disclosure, the surface treating layer 115 is formed on the entire upper surface of the first semiconductor layer 114 of the driving thin film transistor DT or only on the upper surface of the first channel region 114a of the first semiconductor layer 114 of the driving thin film transistor DT, and the surface treating layer 115 is not formed on the upper surface of the second semiconductor layer 174 of the switching thin film transistor ST. Therefore, the S-factor of the driving thin-film transistor (DT) becomes larger than that of the switching thin-film transistor (ST), so that the rich grayscale expression is possible in the driving thin-film transistor (DT) and the fast switching is possible in the switching thin-film transistor (ST), thereby the performance of the organic light emitting display device may be significantly improved.

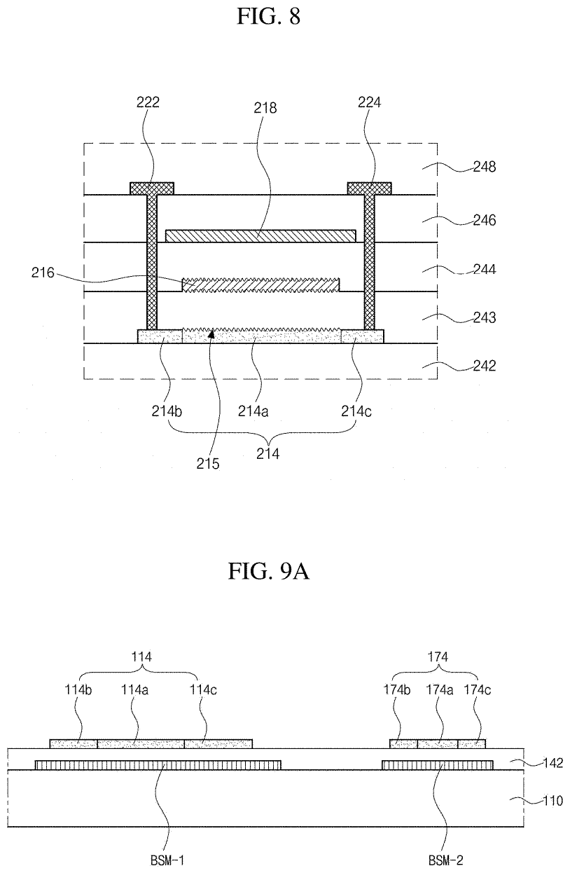

FIG. 8 is a cross-sectional view illustrating the structure of the organic light emitting display device according to a second embodiment of the present disclosure. Since the structure of this embodiment is the same as that of the first embodiment except for the structure of the driving thin film transistor DT, only the driving thin film transistor DT is shown in FIG. 8 for convenience of explanation.

As shown in FIG. 8, in the organic light emitting display device of this embodiment, the first semiconductor layer 214 is disposed on the buffer layer 242. In this case, the first semiconductor layer 214 includes the first channel region 214a in a central region thereof, and the first source region 214b and the first drain region 214c that are doped layers on both sides thereof.

The first semiconductor layer 214 is made of the oxide semiconductor such as indium gallium zinc oxide (IGZO), and the surface treating layer 215 is formed on the upper surface of the first semiconductor layer 214. The surface treating layer 215 may be formed by surface-treating the upper surface of the first semiconductor layer 214 or by disposing the separate surface-treated layer on the first semiconductor layer 214. The surface treating layer 215 may be formed in the curved shape such as the wavy shaped pattern, the polygonal shaped pattern such as the triangle pattern, or concave-convex pattern. The surface treating layer 215 may be formed on the entire upper surface of the first semiconductor layer 214 or only on the upper surface of the first channel region 214a of the first semiconductor layer 214.

The gate insulating layer 243 made of the inorganic material such as SiNx or SiOx is formed on the first semiconductor layer 214, and the first gate electrode 216 is formed on the gate insulating layer 243.

The curved shape such as the wavy shaped pattern, the polygonal shaped pattern such as the triangle pattern, or concave-convex pattern may be formed on the upper surfaces of the gate insulating layer 243 and the first gate electrode 216 which overlaps the surface treating layer 215. The shape of the upper surfaces of the gate insulating layer 243 and the first gate electrode 216 corresponds to the shape of the surface treating layer 215. That is the shapes of the upper surfaces of the gate insulating layer 243, the first gate electrode 216, and the surface treating layer 215 match. In other words, the upper surfaces of the gate insulating layer 243 and the first gate electrode 216 have the same shape as the surface treating layer 215.

Since the gate insulating layer 243 has a relatively thin thickness, the shape of the upper surface of the first semiconductor layer 214 is formed on the upper surface of the gate insulating layer 243 when the gate insulating layer 243 is formed. Further, the same shape is also formed on the upper surface of the first gate electrode 216. However, although the same shape is formed on the upper surfaces of the first semiconductor layer 214, the gate insulating layer 243, and the first gate electrode 216, the shape is alleviated due to the thickness of the gate insulating layer 243 so that the heights of the shape of the upper surface of the first semiconductor layer 214, the gate insulating layer 243, and of the first gate electrode 216 are gradually decreased.

The interlayer insulating layer 244 is deposited on the first gate electrode 216 and the storage electrode 118 is disposed on the interlayer insulating layer 244. In this case, the same shape as the surface treating layer 215 may be formed on the upper surface of the interlayer insulating layer 244 corresponding to the surface treating layer 215. However, since the shape is completely alleviated due to the thickness of the gate insulating layer 243 and the interlayer insulating layer 244, the shape of the surface treating layer 215 may be formed at a fine height on the upper surface of the interlayer insulating layer 244 or the shape of surface treating layer 215 may not formed on the upper surface of the interlayer insulating layer 244.

The passivation layer 246 is formed on the storage electrode 118, and the first source electrode 222 and the first drain electrode 224 are formed on the passivation layer 246. The first source electrode 222 and the first drain electrode 224 are respectively connected to first source region 214b and the first drain region 214c of the first semiconductor layer 214 through contact holes formed in the gate insulating layer 243, the interlayer insulating layer 244, and the passivation layer 246.

As described above, in the organic light emitting display device of this embodiment, the surface treating layer 215 is formed on the entire upper surface of the first substrate semiconductor layer 214 or the upper surface of the first channel region 214 of the first substrate semiconductor layer 214, the upper surface of the gate insulating layer 243, and the upper surface of the first gate electrode 216 of the driving thin film transistor DT, but the surface treating layer 215 is not formed on the upper surface of the second semiconductor layer 247, the gate insulating layer 243, and the second gate electrode 276 of the switching thin film transistor ST. Therefore, since the s-factor of the driving thin film transistor DT is larger than the s-factor of the switching thin film transistor ST, the gradation expression of the driving thin film transistor DT may be rich and the switching speed of the switching thin film transistor ST may be fast. As a result, it is possible to significantly improve the performance of the organic light emitting display device.

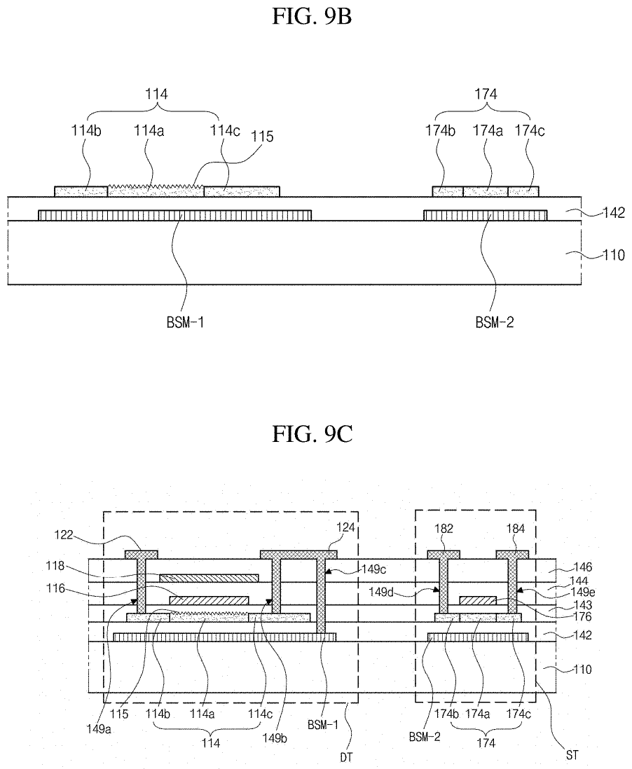

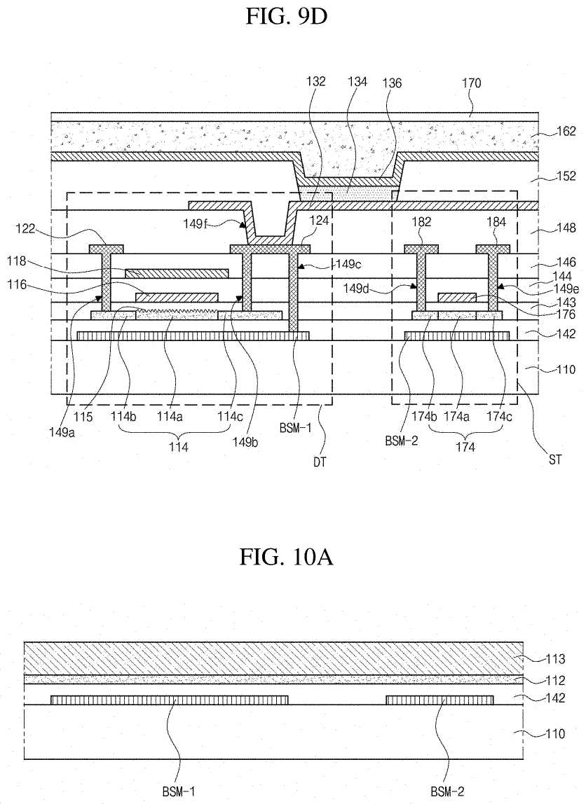

FIGS. 9A to 9D are views illustrating the method of manufacturing the organic light emitting display device according to the first and second embodiments of the present disclosure. At this time, for convenience of description, the structure of the first embodiment will be described as an example.

First, as shown in FIG. 9A, the metal is deposited on the first substrate 110 made of the flexible material such as plastic by sputtering and etched the deposited metal to form the first lower blocking metal layer BSM_1 and the second lower blocking layer BSM_2, and then the buffer layer 142 is formed by deposition the inorganic material such as SiOx or SiNx as the single layer or the multi layers by a chemical vapor deposition (CVD) method or the like.

Thereafter, the oxide semiconductor such as IGZO is deposited on the buffer layer 142 and then etched to form the first semiconductor layer 114 and the second semiconductor layer 174. At this time, the impurities are doped into both side regions of the first semiconductor layer 114 and the second semiconductor layer 174 to form the first and second channel regions 114a, 174a, the first and second source regions 114b, 174b, and the first and second drain regions 114c, 117c.

Subsequently, as shown in FIG. 9B, the surface treating layer is formed on the entire upper surface of the first semiconductor layer 114 or the upper surface of the first channel region 114a of the first semiconductor layer 114. The surface treating layer 115 may be formed by depositing the separate surface-treated semiconductor oxide pattern on the upper surface of the first semiconductor layer 114, or may be formed by directly surface-treating the upper surface of the first semiconductor layer 114.

Thereafter, as shown in FIG. 9C, the gate insulating layer 143 is formed by depositing the inorganic material such as SiOx or SiNx in the single layer or the multi layers by the Chemical Vapor Deposition (CVD) method on the semiconductor layer 114, and then the metal layer is deposited thereon and etched to form the first gate electrode 116 and the second gate electrode 176.

Subsequently, the inorganic material is deposited to form the interlayer insulating layer 144 composed of the single layer or the multi layers, and then the metal is stacked thereon and etched to form the storage electrode 118.

Thereafter, the passivation layer 146 is formed by depositing the organic material and then the gate insulating layer 143, the interlayer insulating layer 144, and the passivation layer 146 above the first source region 114b and the first drain region 114c of the first semiconductor layer 114 and the second source region 174b and the second drain region 174c of the second semiconductor layer 174 are etched to form the first contact hole 149a, the second contact hole 149b, the fourth contact hole 149d, and a fifth contact hole 1493. Further, the buffer layer 142, the gate insulating layer 143, the interlayer insulating layer 144, and the passivation layer above the first lower blocking metal layer BSM_1 is etched to form the third contact hole 149c. Subsequently, the metal is deposited on the passivation layer 146 and etched to form the first source electrode 122, the first drain electrode 124, the second source electrode 182, and the second drain electrode 184 to form the driving thin film transistor DT and the switching thin film transistor ST.

At this time, the first source electrode 122 and the second source electrode 182 are respectively connected to the first source region 114b of the first semiconductor layer 114 and the second source region 174b of the second semiconductor layer 174 through the first and second contact holes 149a and 149b. The first drain electrode 124 and the second drain electrode 184 are respectively connected to the first drain region 114c of the first semiconductor layer 114 and the second drain region 174c of the second semiconductor layer 174 through the fourth and fifth contact holes 149d and 149e. The first drain electrode 124 of the first semiconductor layer 114 is connected to the first lower blocking metal layer BSM_1 through the third contact hole 149c.

Thereafter, as shown in FIG. 9D, the transparent conductive material such as ITO or IZO is deposited on the passivation layer 146 and etched to form the second electrode 132. At this time, the second electrode 132 is electrically connected to the first drain electrode 124 of the driving thin film transistor DT through the sixth contact hole 149f formed in the passivation layer 146.

Subsequently, after forming the bank layer 152 having an opening on the passivation layer 148 on which the second electrode 132 is formed, the organic light emitting material is coated to the opening of the bank layer 152 to form the organic light emitting layer 134. thereafter, the metal is deposited in a thickness of several tens of nm by sputtering over the entire area of the upper portion of the organic light emitting layer 134 and etched to form the first electrode 136.

Thereafter, the inorganic materials such as SiNx and SiX and organic materials such as polyethylene terephthalate, polyethylene naphthalate, polycarbonate, polyimide, polyethylene sulfonate, polyoxymethylene and polyarylate are deposited on the first electrode 136 to from encapsulating layer 162.

Thereafter, an adhesive layer (not shown in figure) is coated on the encapsulating layer 162 and then the second substrate 170 is disposed. The adhesive layer is cured to complete an organic light emitting display device.

As described above, in the organic light emitting display device according to the present disclosure, the first semiconductor layer 114 may be formed by depositing the oxide semiconductor, surface-treating the partial region of the upper surface thereof to form a surface treating layer 115, and then patterning the deposited oxide semiconductor. Hereinafter, the method of forming the first semiconductor layer 114 will be described in more detail.

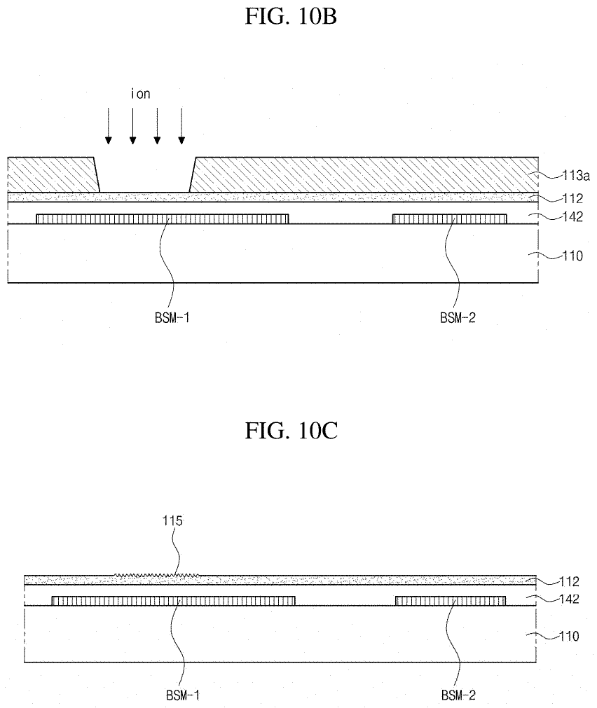

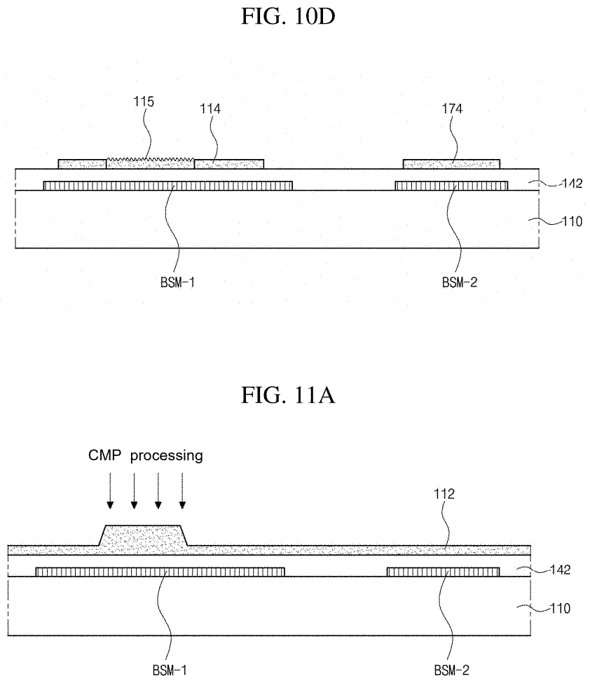

FIGS. 10A to 10D are views illustrating an example of the method of forming the first and second semiconductor layers 114 and 174 of an organic light emitting display device.

First, as shown in FIG. 10A, the gate insulating layer 142 composed of the single inorganic layer or the multi inorganic layers made of the inorganic material such a as SiOx or SiNx and the oxide semiconductor layer 112 are sequentially deposited on the first substrate 110 on which the first and second lower blocking metal layers BSM_1 and BSM_2 are disposed, and then a photoresist layer 113 is formed thereon.

Thereafter, as shown in FIG. 10B, the photoresist layer 113 is developed to form a photoresist pattern 113a exposing a portion of the oxide semiconductor layer 112 and then ions are irradiated using the photoresist pattern 113a as a blocking mask to collide with the exposed surface of the oxide semiconductor layer 112.

As shown in FIG. 10C, traces are generated in the exposed oxide semiconductor layer 112 by the collision, and the surface treating layer 115 is formed by these traces, thereby increasing the roughness of the oxide semiconductor layer 112.

After removing the photoresist pattern 113a, as shown FIG. 10D, the oxide semiconductor layer 112 is etched to form the first semiconductor layer 114 having upper surface surface-treated (i.e., the surface treating layer 115 is formed) and the second semiconductor layer 174 which is not surface-treated.

As not shown in figures, the impurities are doped to both sides of the first semiconductor layer 114 and the second semiconductor layer 174 to form respectively the source region and the drain region in the first semiconductor layer 114 and the second semiconductor layer 174.

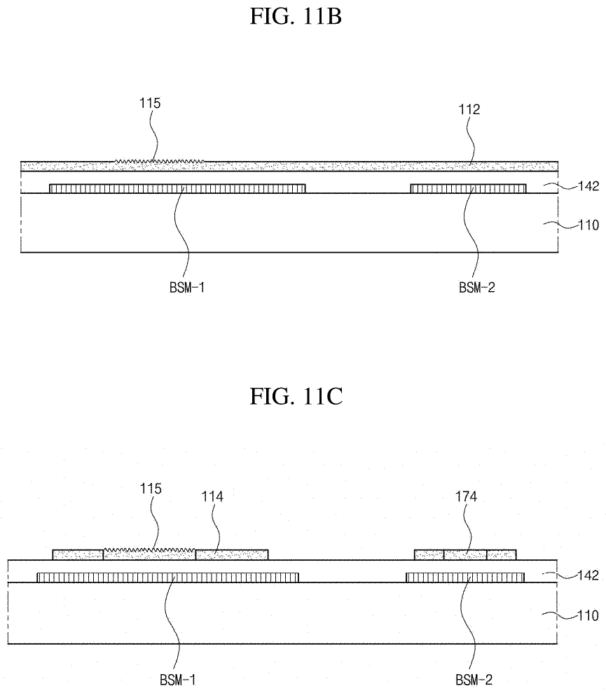

FIGS. 11A to 11C are vies illustrating another example of the method of forming the first and second semiconductor layers 114 and 174 of the organic light emitting display device.

First, as shown in FIG. 11A, the gate insulating layer 142 composed of the single inorganic layer or the multi inorganic layers made of the inorganic material such a as SiOx or SiNx and the oxide semiconductor layer 112 are sequentially deposited on the first substrate 110 on which the first and second lower blocking metal layers BSM_1 and BSM_2 are disposed.

In this case, the oxide semiconductor layer 112 has a stepped structure. That is, the thickness of the oxide semiconductor layer 112 of the region in which the first semiconductor layer of the driving thin film transistor DT is to be formed or the channel region of the first semiconductor layer is formed is larger than that of the other regions. This stepped structure may be formed by depositing the photoresist on the oxide semiconductor layer 112 and then developing the photoresist using a halftone mask or a diffraction mask. Further, the stepped structure may be formed by depositing the oxide semiconductor layers 112 of different thicknesses by two processes.

Thereafter, as shown in FIG. 11B, the oxide semiconductor layer 112 in the thick region is polished by CMP (Chemical Mechanical Polishing) to planarize the entire oxide semiconductor layer 112 so that the thickness of the oxide semiconductor layer 112 becomes the same in whole area thereof. The oxide semiconductor layer 112 in the region polished by CMP has a roughness different from that in other regions. That is, the oxide semiconductor layer 112 in this region is surface-treated by CMP to form the surface-treated layer 115. In this case, by appropriately selecting a polishing pad and an abrasive for performing CMP, it is possible to form surfaces of various roughness.

Subsequently, as shown in FIG. 11C, the oxide semiconductor layer 112 is etched to form the first semiconductor layer 114 with the surface-treated upper surface and the second semiconductor layer 174 that is not surface-treated. Further, although not shown in the figures, by implanting impurities into both sides of each of the first semiconductor layer 114 and the second semiconductor layer 174, the source regions, the drain region, and the channel region are formed in each of the first semiconductor layer 114 and the second semiconductor layer 174.

As described above, in the organic light emitting display device according to the present disclosure, the surface treating layer is formed by surface treating of the first semiconductor layer 114 by ion implantation and CMP, but the present invention is not limited to this method. The surface will be treated by various methods. For example, the layer having a separate roughness may be formed on the entire first semiconductor layer 114 or on the first channel region.

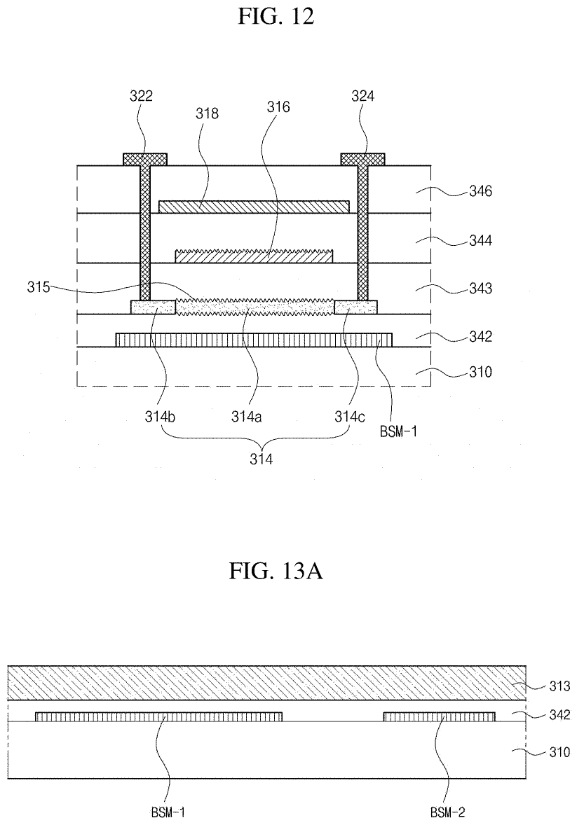

FIG. 12 is the cross-sectional view illustrating the structure of the organic light emitting display device according to a third embodiment of the present disclosure. Since the structure of this embodiment is the same as that of the first embodiment except that the structure of the driving thin film transistor DT, only the driving thin film transistor DT is shown in FIG. 12 for convenience of explanation.

As shown in FIG. 12, in the organic light emitting display device of this embodiment, the buffer layer 342 is formed on the first substrate 310 having the first lower blocking metal layer BSM_1, and the first semiconductor layer 314 is formed on the buffer layer 342. In this case, the first semiconductor layer 314 includes the first channel region 314a in the central region, and the first source region 314b and the first drain region 314c which are doped in both sides.

The upper surface of a portion of the buffer layer 342 corresponding to the first semiconductor layer 314 (or the first channel region 314a) is surface treated to have a roughness (e.g., a pattern of protrusions). That is, the curved shape pattern of protrusions, the polygonal shape such as the triangle pattern of protrusions, or concave-convex pattern of protrusions is formed on the upper surface of a partial region of the buffer layer 342 that overlaps the lower portion of the first semiconductor layer 314 (or the first channel region 314a).

The first semiconductor layer 314 is made of the oxide semiconductor such as IGZO, and a surface treating layer 315 is formed on the first channel region 314a. The surface treating layer 315 is formed at the same position as the surface-treated region of the buffer layer 342, and has the same shape as the surface-treated shape of the buffer layer 342. That is, when a portion of the buffer layer 342 is surface treated in various shapes, the surface treating layer 315 having the same shape is also formed on the upper surface of the first semiconductor layer 314 above the buffer layer 342.

The gate insulating layer 343 made of the inorganic material such as SiNx or SiOx is formed on the first semiconductor layer 314, and the first gate electrode 316 is formed on the gate insulating layer 343.

A curved shape, the polygonal shape, or the concave-convex shape may also be formed on the upper surface of the gate insulating layer 343 and the upper surface of the first gate electrode 316 corresponding to the surface treating layer 315. The shape of the upper surface of the gate insulating layer 343 and the upper surface of the first gate electrode 316 corresponds to the surface-treated shape of the buffer layer 342. In other words, the upper surface of the gate insulating layer 343 and the upper surface of the first gate electrode 316 have the same shape as the surface-treated upper surface of the buffer layer 342.

The interlayer insulating layer 344 is formed on the first gate electrode 316, and the storage electrode 318 is disposed on the interlayer insulating layer 344. The passivation layer 346 is formed on the storage electrode 318, and the first source electrode 322 and the first drain electrode 324 are formed on the passivation layer 346. The first source electrode 322 and the first drain electrode 324 are respectively connected to the first source region 314b and the first drain region 314c of the first semiconductor layer 314 through contact holes formed in the gate insulating layer 343, the interlayer insulating layer 344, and the passivation layer 346.

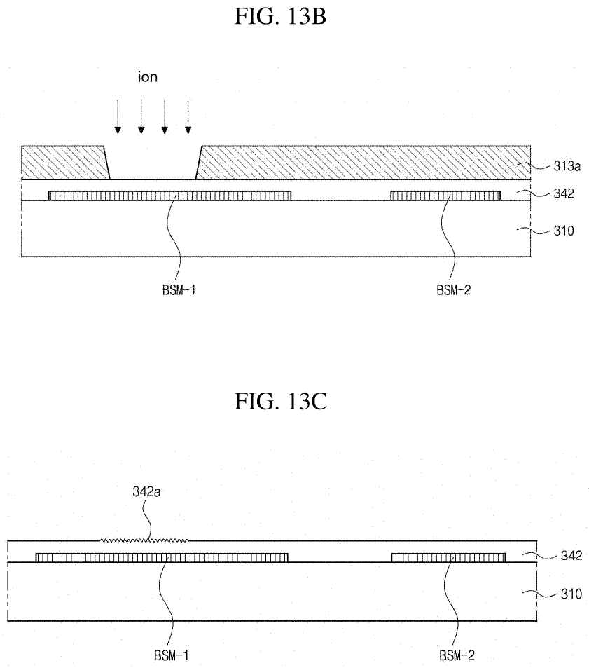

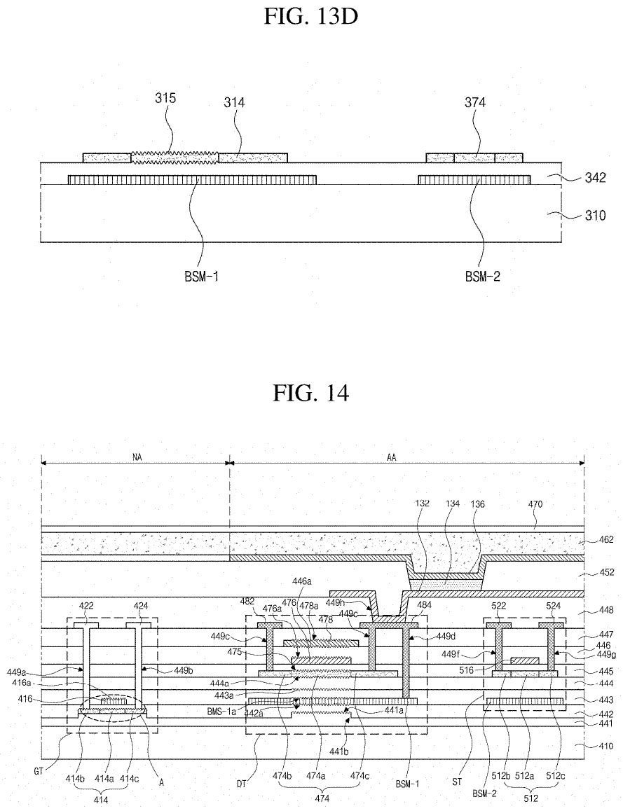

As described above, in the organic light emitting display device of this embodiment, the surface treating layer 315 caused by the surface treating of the buffer layer 342 is formed on the entire upper surface of the first semiconductor layer 314 of the driving thin film transistor DT or on the upper surface of the first channel region 314a of the first semiconductor layer 314 of the driving thin film transistor DT, but the surface treating layer 315 is not formed on the second semiconductor layer of the switching thin film transistor. Therefore, the S-factor of the driving thin film transistor DT is larger than that of the switching thin film transistor, so that the grayscale expression can be enriched in the driving thin film transistor DT, and the switching speed can be increased in the switching thin film transistor. As a result, it is possible to significantly improve the performance of the FIGS. 13A to 13D are views illustrating the method of forming the semiconductor layer of the organic light emitting display device according to the third embodiment of the present invention.

As shown in FIG. 13A, the gate insulating layer 342 composed of the single inorganic layer or the multi inorganic layers of inorganic materials such as SiOx or SiNx is formed on the first substrate 310 having the first and second lower blocking metal layer BSM_1 and BSM_2 and then the photoresist layer 313 is formed on the gate4 insulating layer.

Subsequently, as shown in FIG. 13B, the photoresist layer 313 is developed to form the photoresist pattern 313a exposing a portion of the gate insulating layer 342. Thereafter, ions are irradiated using the photoresist pattern 313a as a blocking mask to collide with the exposed surface of the gate insulating layer 342.

As shown in FIG. 13C, traces are generated in the exposed gate insulating layer 342 by the collision, and the surface treating layer 342 having the roughness larger than that of other region is formed on the upper surface of the gate insulating layer by the traces. That is, the surface treating layer 342 such as the curved shape, the polygonal shape, and the concave-convex is formed on the gate insulating layer 342 of the corresponding region.

Thereafter, after the photoresist pattern 313a is removed, as shown in FIG. 13D, the oxide semiconductor is deposited and etched to form the first semiconductor layer 314 and the second semiconductor layer 374. At this time, since the first semiconductor layer 314 is disposed on the surface-treated region of the gate insulating layer 342, the surface treating layer 315 having the roughness larger than that of other region is formed on a portion of the first semiconductor layer 314 (or entire area on the first semiconductor layer 314) corresponding to the surface treating layer 342 of the gate insulating layer 342 by the surface treating layer 342 of the gate insulating layer.

Meanwhile, the impurities are implanted on both sides of each of the first semiconductor layer 314 and the second semiconductor layer 374 so that the source region, the drain region, and the channel region are formed in each of the first semiconductor layer 314 and the second semiconductor layer 374.

As described above, in the organic light emitting display device of this embodiment, surface threating layers 342a and 315 are respectively formed on some or all of the gate insulating layer 342 and the first semiconductor layer 314. By this surface treating 315, the gradation expression can be enriched in the driving thin film transistor DT and the switching speed can be improved in the switching thin film transistor ST, so that the performance of the organic light emitting display device can be significantly improved.

FIG. 14 is the cross-sectional view illustrating the structure of then organic light emitting display device according to a fourth embodiment of the present disclosure.

In the organic light emitting display device having this structure, the oxide thin film transistors are used for the driving thin film transistors and the switching thin film transistors disposed in the display area including a plurality of pixels to display the actual image, and the polycrystalline thin film transistor is used for the thin film transistor in the non-display area where the image is not displayed, especially GIP (Gate In Panel) thin film transistor.

In general, since the polycrystalline semiconductor has faster electric mobility than the oxide semiconductor, the polycrystalline semiconductor is suitable as the thin film transistor for the gate driver disposed in GIP that require faster switching speed.

That is, in the organic light emitting display device of this embodiment, the performance of the organic light emitting display device is optimized by differentiating the electrical characteristics of the thin film transistor disposed in the non-display area and the driving thin film transistor and the switching thin film transistor disposed in the display area.

As shown in FIG. 14, the display device according to the fourth embodiment of the present disclosure includes the display area AA in which the image is displayed and the non-display area NA outside the display area AA. The driving thin film transistor DT and the switching thin film transistor ST are disposed in the display area AA, and the gate thin film transistor GT is disposed in the GIP of the non-display area NA.

At this time, although one switching thin film transistor ST is disposed in the figure, a plurality of the switching thin film transistors ST may be disposed. Further, a plurality of gate thin film transistors GT may also be disposed to form a circuit such as a shift register and a level shifter.

The gate thin film transistor GT includes the first semiconductor layer 414 on the first buffer layer 441 formed over the entire first substrate 410, the first gate insulating layer 442 on the first buffer layer 441 to cover the first semiconductor layer 141, the first gate electrode 416 on the first gate insulating layer 442, the first interlayer insulating layer 443 on the first gate insulating layer 442 to cover the first gate electrode 416, the second buffer layer 444 on the first interlayer insulating layer 443, the second gate insulating layer 445 on the second buffer layer 444, the second interlayer insulating layer 446 on the second gate insulating layer 445, the passivation layer on the second gate insulating layer 445, and the source electrode 422 and the second drain electrode 424 on the passivation layer 447.

The first substrate 410 may be made of the flexible plastic material, but is not limited thereto and the first substrate 410 may be made of the hard transparent material such as glass.

The first buffer layer 441 is formed to protect the thin film transistor formed in the subsequent process from the impurities such as alkali ions leaking from the first substrate 410 or to block moisture that may penetrate from the outside. The first buffer layer 441 may be formed of the single layer or the multi layers made of the inorganic material such as SiOx and SiNx.

The first semiconductor layer 414 may be formed of the crystalline semiconductor such as the polycrystalline silicon. In this case, the first semiconductor layer 414 includes the first channel region 414a in the central region and the first source region 414b and the first drain region 414c that are doped layers on both sides.

The first gate insulating layer 442 may be formed of the single layer or the multi layers made of the inorganic material such as SiOx and SiNx, and the first gate electrode 416 may be formed of the single layer or the multi layers made of the metal such as Cr, Mo, Ta, Cu, Ti, Al or Al alloy. Further, the first interlayer insulating layer 444 may be formed of the single layer or the multi layers made of the inorganic material of SiOx and SiNx, and the second buffer layer 444 may be formed of the single layer or the multi layers made of the inorganic material such as SiOx and SiNx.

The second gate insulating layer 445 may be formed of the single layer or the multi layers made of the inorganic material such as SiOx and SiNx, and the second interlayer insulating layer 446 may be formed of the single layer or the multi layers made of the inorganic material such as SiOx and SiNx. Further, the passivation layer 447 may be made of the organic material such as photo acryl.

The first source electrode 422 and the first drain electrode 424 may be formed of the single layer or the multi layers made of the metal such as Cr, Mo, Ta, Cu, Ti, Al, or an Al alloy. The first source electrode 422 and the first drain electrode 424 are respectively connected to the first source region 414b and the first drain region 414c of the first semiconductor layer 414 t through the first contact hole 449a and the second contact hole 449b formed in the first gate insulating layer 442, the first interlayer insulating layer 443, the second buffer layer 444, the second gate insulating layer 446, the second interlayer insulating layer 446, and the passivation layer 447.

The driving thin film transistor DT includes the first lower blocking metal layer BSM_1 on the first gate insulating layer 442, the second semiconductor layer 474 on the second buffer layer 444, the second gate electrode 476 on the second gate insulating layer 445, the storage electrode 478 on the second interlayer insulating layer 446, and the second source electrode 482 and the second drain electrode 484 on the passivation layer 447.

The first lower blocking metal layer BSM_1 reduces the back-channel phenomenon caused by charges trapped from the first substrate 410 to prevent the afterimage or deterioration of transistor performance. The first lower blocking metal layer BSM_1 may be formed of the single layer or the multi of layers made of Ti, Mo, or the alloy of Ti and Mo, but is not limited thereto.

The second semiconductor layer 474 is made of the oxide semiconductor, and includes the second channel region 474a in the central region and the doped second source and drain regions 474b and 474c in both sides.

The surface treating layer 475 is formed on the upper surface of the second semiconductor layer 474. The surface treating layer 715 imparts roughness to the surface of the second semiconductor layer 474. The S-factor of the driving thin film transistor DT is increased by this surface treating layer 475.

The surface treating layer 475 may be formed over the entire upper surface of the second semiconductor layer 474 or may be formed only on the upper surface of the second channel region 474a. In addition, the surface treating layer 475 may be formed integrally with the second semiconductor layer 474 by directly surface-treating the upper surface of the second semiconductor layer 474.

The second gate electrode 476 may be formed of the single layer or the multi layers of the metal such as Cr, Mo, Ta, Cu, Ti, Al, or Al alloy, but is not limited thereto. Further, the storage electrode 478 may be formed of the metal, but is not limited thereto.

The second source electrode 482 and the second drain electrode 484 may be formed of the single layer or the multi layers made of the metal such as Cr, Mo, Ta, Cu, Ti, Al, or an Al alloy. The second source electrode 482 and the second drain electrode 484 are respectively connected to the second source region 474b and the second drain region 474c of the second semiconductor layer 474 t through the third contact hole 449c and the fourth contact hole 449d formed in the second gate insulating layer 445, the second interlayer insulating layer 446, and the passivation layer 447.

Further, the second drain electrode 474 is connected to the first lower blocking metal layer BSM_1 through the fifth contact hole 449e formed in the first interlayer insulating layer 443, the second buffer layer 444, the second gate insulating layer 445, the second interlayer insulating layer 446, and the passivation layer 447.

The switching thin film transistor ST includes the second lower blocking metal layer BSM_2 on the first gate insulating layer 442, the third semiconductor layer 514 on the second buffer layer 444, the third gate electrode 516 on the second gate insulating layer 445, and the third source electrode 522 and the third drain electrode 524 on the passivation layer 447.

The second lower blocking metal layer BSM_2 is made of the same metal as the first gate electrode 416 of the gate thin film transistor GT on the same layer thereof, but is not limited thereto and may be made of the different metal on a different layer.

The third semiconductor layer 514 is made of the oxide semiconductor, and includes the third channel region 514a in the central region and the doped third source and drain regions 514b and 514c in both sides.

The third gate electrode 516 may be formed of the single layer or the multi layers made of the metal such as Cr, Mo, Ta, Cu, Ti, Al, or an Al alloy, but is not limited thereto.

The third source electrode 522 and the third drain electrode 524 may be formed of the single layer or the multi layers made of the metal such as Cr, Mo, Ta, Cu, Ti, Al, or an Al alloy. The third source electrode 522 and the third drain electrode 5244 are respectively connected to the second third region 214b and the third drain region 514c of the third semiconductor layer 514 through the sixth contact hole 449f and the seventh contact hole 449g formed in the second gate insulating layer 445, the second interlayer insulating layer 446, and the passivation layer 447.

The planarization layer 448 is formed on the substrate 410 on which the gate thin film transistor GT, the driving thin film transistor DT, and the switching thin film transistor ST are disposed. The planarization layer 448 may be formed of the organic material such as photoacrylic, but may also formed of a plurality of layers including the inorganic layer and the organic layer. An eighth contact hole 449h is formed in the planarization layer 448.

The first electrode 432 is formed on the planarization layer 448. The first electrode 432 is electrically connected to the second drain electrode 484 of the driving transistor DT through the eighth contact hole 249h. The first electrode 432 is made of the single layer or the multi layers made of the metal such as Ca, Ba, Mg, Al, Ag, or an alloy thereof, and is connected to the second drain electrode 484 of the driving transistor DT so that the image signal is applied to the first electrode 432 from outside.

The bank layer 452 is formed at the boundary between each sub-pixel SP on the planarization layer 448. The organic light emitting layer 434 is formed on the first electrode 432 and on a portion of the inclined surface of the bank layer 452. The organic light emitting layer 434 may be an R-organic light emitting layer to emit red light, the G-organic light emitting layer to emit green light, and the B-organic light emitting layer to blue light which are formed in the R, G, and B pixels. Further, the organic light emitting layer 434 may be the W-organic light emitting layer to emit white light.

The organic light emitting layer 434 may further include the electron injection layer and the hole injection layer for respectively injecting electrons and holes into the organic layer, and the electron transport layer and the hole transport layer for respectively transporting the injected electrons and holes to the organic layer.

The second electrode 436 is formed on the organic light emitting layer 434. The first electrode 436 may be made of the transparent conductive material such as ITO or IZO, or a thin metal through which visible light is transmitted, but is not limited thereto.

The encapsulating layer 462 is formed on the second electrode 436. The encapsulating layer 462 may include the single layer composed of the inorganic layer. Further, the encapsulating layer 462 may include two layers of the inorganic layer/organic layer, or may include three layers of the inorganic layer/organic layer/inorganic layer.

The second substrate 470 is attached to the encapsulating layer 462 by an adhesive layer (not shown in figure). In this case, the adhesive layer may be made of a thermosetting resin or photocurable resin such as an epoxy-based compound, an acrylate-based compound, or an acrylic rubber.

As described above, in the organic light emitting display device according to this embodiment, both the driving thin film transistor DT and the switching thin film transistor ST disposed in the sub-pixel SP of the display area AA are oxide thin film transistors, and the gate thin film transistor GT disposed in the gate driving unit in the non-display area is the crystalline thin film transistor.

Accordingly, since the switching speed of the gate thin film transistor GT is much faster than that of the driving thin film transistor DT and the switching thin film transistor ST, the data processing speed in the gate driving unit is improved.

In addition, since the surface treating layer 475 is formed on the upper surface of the second semiconductor layer 474 of the driving thin film transistor DT and is not formed on the upper surface of the third semiconductor layer 514 of the switching thin film transistor ST, the S-factor of the driving thin film transistor DT is larger than that of the switching thin film transistor ST. Therefore, the driving thin film transistor DT has electrical characteristics advantageous for grayscale expression to enable rich grayscale expression of images and the switching speed of the switching thin film transistor ST is faster than that of the driving thin film transistor DT, so that the image having high quality can be displayed.

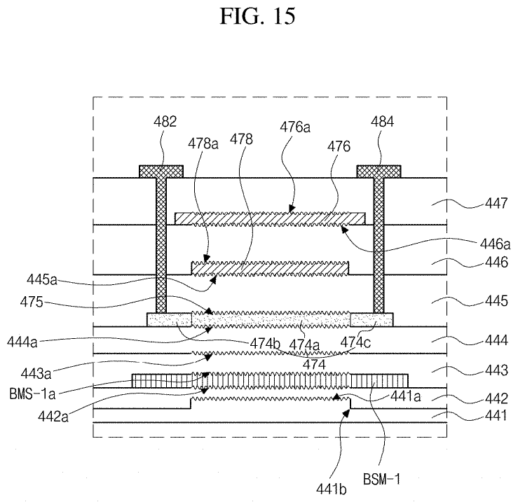

In the driving thin film transistor DT of this embodiment, on the other hand, the surface treating layer 475 is not formed only on the upper surface of the second semiconductor layer 474, but also on the upper surface of the layer disposed below the second semiconductor layer 474. This structure will be described in detail with reference to FIG. 15.

FIG. 15 is the enlarged cross-sectional view of the driving thin film transistor DT according to the fourth embodiment of the present disclosure.

As shown in FIG. 15, the surface treating layers 441a, 442a, BSM_1a, 443a, and 444a are respectively formed in the areas corresponding to (e.g., overlapping) the second channel region 474a of the first buffer layer 441, the first gate insulating layer 442, the first lower blocking metal layer BSM_1, the first interlayer insulating layer 443, and the second buffer layer 444 disposed below the second semiconductor layer 474.

The surface treating layer 441a is formed on a portion of the upper surface of the first buffer layer 441 by the polycrystalline surface characteristic of the first semiconductor layer 414 of the gate thin film transistor GT, and the surface treating layers 442a, BSM_1a, 443a, and 444a are also formed on the layers above the first buffer layer 441 by the surface treating layer 441a, whereby a portion of the upper surface of the layer disposed under the second semiconductor layer 474 is also surface-treated. This will be described in detail in the following manufacturing method.

As shown in the FIG. 15, the surface treating layers 445a, 476a, 446a, 478a are formed on the upper surface of the second gate insulating layer 445, the second gate electrode 476, the second interlayer insulating layer 446, and the storage electrode 478 disposed over the second semiconductor layer 474. The surface treating layers 445a, 476a, 446a, and 478a are also formed by the polycrystalline surface properties of the first semiconductor layer 414 of the gate thin film transistor GT.

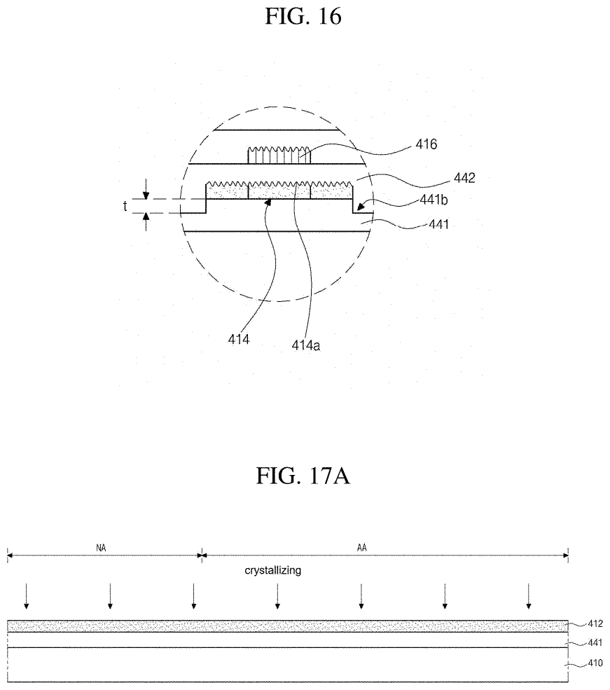

FIG. 16 is an enlarged view of region A of FIG. 14, and is the cross-sectional view illustrating the upper and lower structures of the first semiconductor layer 414.

As shown in FIG. 16, the first semiconductor layer 414 is formed on the first buffer layer 441, and the first gate insulating layer 442 is formed on the first gate insulating layer 442. At this time, the first buffer layer 441 under the first semiconductor layer 414 protrudes upward to form a step 441b. That is, the thickness of the first buffer layer 441 under the first semiconductor layer 414 is thicker by t than that of another region of the first buffer layer 441.

This step 441b is formed by the manufacturing method to be described later, which will be described in more detail in the manufacturing method.

A protrusion 414a is formed on the upper surface of the first semiconductor layer 414. The protrusion 414a is formed because the first semiconductor layer 414 is made of the polycrystalline semiconductor. That is, the amorphous semiconductor is crystallized by heat treatment or laser irradiation, and crystallization is performed in units of grains. Accordingly, since the crystallized first semiconductor layer 414 includes a plurality of grains, a discontinuous plane is generated between the plurality of grains. As the plurality of grains overlap, the surface of the first semiconductor layer 414 does not become smooth and flat, but a plurality of irregular protrusions 414a are formed by the overlapping of the grains. The plurality of protrusions 414a causes the increase in the roughness of the upper surface of the first semiconductor layer 414, and the upper surface of the layers above the first semiconductor layer 414 also increase in roughness due to the shape of the upper surface of the first semiconductor layer 414.

Since the roughness of the upper surface of the first semiconductor layer 414 increases the S-factor, the electrical characteristics of the gate thin film transistor GT, i.e., the switching speed, are reduced. In a gate thin film transistor GT made of the crystalline semiconductor, however, since the change in the switching speed according to the increase of the S-factor is negligible compared to the switching speed, the actual change of the electrical characteristics of the gate thin film transistor GT according to the increase of the roughness of the upper surface of the first semiconductor layer 414 (i.e., according to the formation of the protrusion 414a) is very small.

That is, in this embodiment, the effect of the protrusions 414a on the upper surface of the first semiconductor layer 414 is very insignificant, so that the protrusions on the upper surface of the first semiconductor layer 414 are ignored in FIG. 14.

As described above, in the organic light emitting display device according to this embodiment, the gate thin film transistor GT, the driving thin film transistor DT, and the switching thin film transistor ST having different electrical characteristics are disposed on the substrate. In this case, the driving thin film transistor DT and the switching thin film transistor ST are formed in the same structure having the oxide semiconductor layer and then the semiconductor layer of the driving thin film transistor is surface treated, so that the process can be simplified, and the manufacturing cost can be reduced.

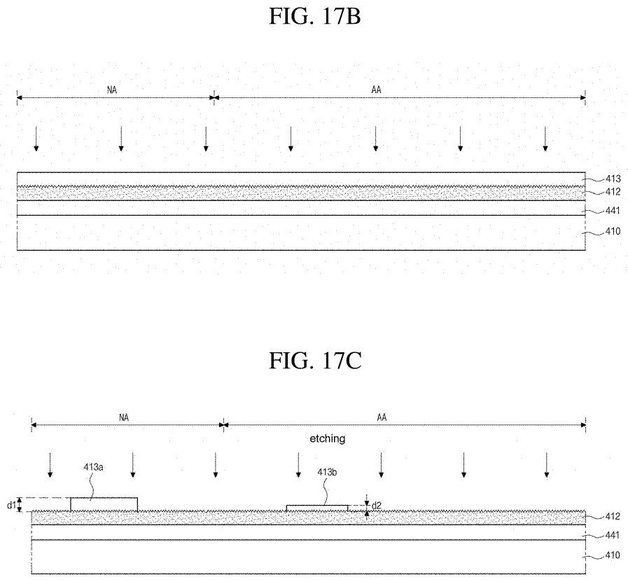

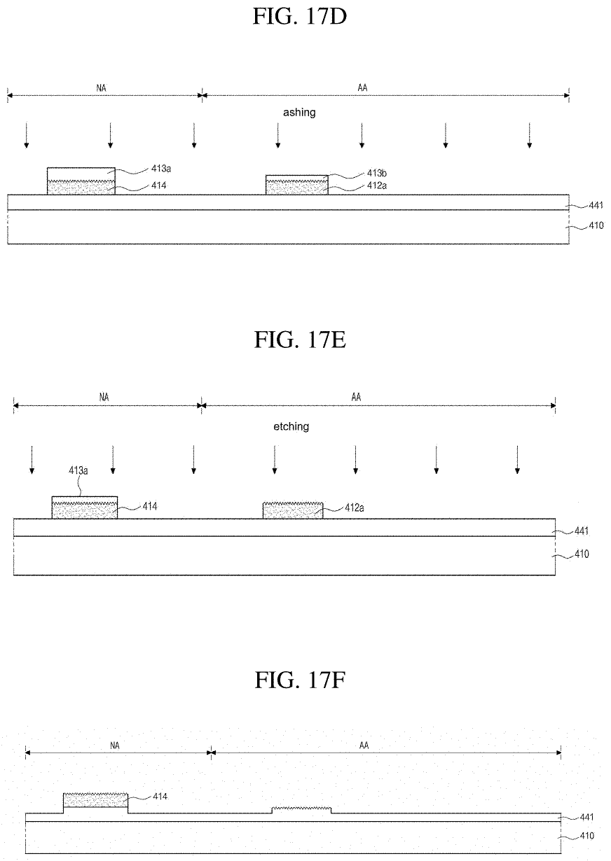

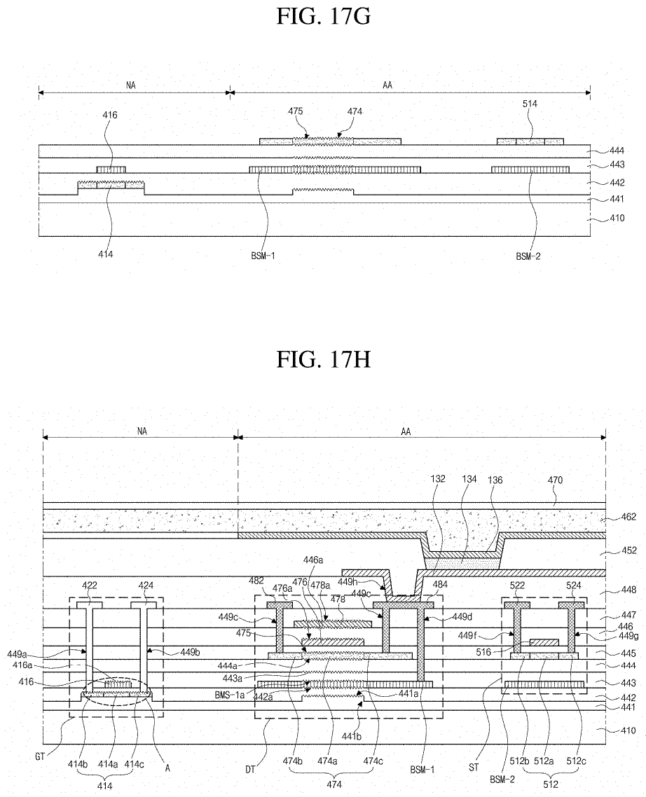

FIGS. 17A-17H are views illustrating the method of manufacturing the organic light emitting display device according to the fourth embodiment of the present invention.

First, as shown in FIG. 17A, the inorganic material such as SiOx or SiNx is deposed on the first substrate 410 made of the flexible material such as the plastic and including the display area AA and the non-display area NA by the CVD method to form the first buffer layer 441 composed of the single layer or the multi layers, and then a semiconductor material layer 412 by depositing the amorphous material. At this time, the first buffer layer and the semiconductor material layer 412 may be sequentially deposited or deposited by the separate processes.

Thereafter, as shown in FIG. 17B, heat is applied to the semiconductor material layer 412 in the amorphous state or an excimer laser is irradiated to the semiconductor material layer 412 in the amorphous state to crystallize the semiconductor material layer 412 into the polycrystalline state. Since the semiconductor material layer 412 in the amorphous state is crystallized in units of grains and the crystalline state is grown in units of grains, the semiconductor material layer 412 in the polycrystalline state includes the plurality of grains.

Accordingly, the discontinuous step occurs in the boundary region between the plurality of grains, and the non-flat surface such as the irregular protrusion 412a is formed on the upper surface of the semiconductor material layer 412 by this discontinuous step.

Subsequently, the photoresist layer 413 is deposited on the semiconductor material layer 412 in the poly crystalline state and then developed the photoresist layer 413 using a half tone mask or a diffraction mask to form respectively first and second photoresist patterns 413a and 413b in the non-display area NA and the display area AA as shown in FIG. 17C. At this time, the thickness of the first photoresist pattern 413a is larger than that of the second photoresist pattern 413b (d1>d2).

Thereafter, as shown in FIG. 17D, the semiconductor material layer 412 in the poly crystalline state is etched using the first and second photoresist patterns 413a and 413b as a blocking mask to form the first semiconductor layer 414 in the non-display area NA and from the semiconductor pattern 412a in the display area AA, and then the first and second photoresist patterns 413a and 413b are ash. By ashing process, the second photoresist pattern 413b is completely removed to expose the semiconductor pattern 412a to the outside and the first photoresist pattern 413a remains on the first semiconductor layer (414) with a reduced thickness.

Thereafter, as shown FIG. 17E, the semiconductor pattern 412a and the first buffer layer 441 are etched by using the first photoresist pattern 413 as the blocking mask.

Subsequentially, as shown in FIG. 17F, when removing the first photoresist pattern 413a, the semiconductor layer 412a is removed by etch and the upper part of the first buffer layer 441 is removed to a certain thickness so that the thickness of the first buffer is reduced. However, since area of the first semiconductor layer 414 blocked by the first photoresist pattern 413a and the first buffer layer 441 under thereof is not etched, the thickness of the first buffer layer 441 under the first semiconductor layer 414 is larger than that of the other area of the first buffer layer 441, so that the step is formed in the first buffer layer 441.

In addition, in the region of the display area AA where the semiconductor pattern 412a was located, the semiconductor pattern 412a is etched and then the first buffer layer 441 under thereof is etched. Accordingly, the unevenness of the upper surface of the semiconductor pattern 412a is transferred to the first buffer layer 441, so that the non-planar surface such as unevenness is formed in a partial area of the upper surface of the first buffer layer 441.

Subsequently, as shown in FIG. 17G, the inorganic material such as SiOx or SiNx is deposited over the entire first substrate 442 to form the first gate insulating layer 442 including the single layer or the multi layers. Thereafter, the metal is deposited on the first gate insulating layer 442 and etched to form the first gate electrode 416 in the non-display area NA and the first lower blocking metal layer BSM_1 and the second lower blocking metal layer BSM_2 in the display area AA.

Thereafter, the second interlayer insulating layer 443 having the single layer or the layers is formed by depositing the inorganic material such as SiOx and SiNx, and the second buffer layer 444 is formed thereon. Thereafter, the second semiconductor layer 474 and the third semiconductor layer 514 are formed on the second buffer layer 444 in the display area AA by depositing and etching the oxide semiconductor. At this time, due to the non-planarized shape (for example, uneven shape) of the first buffer layer 441 in the display area AA, the non-planarized surface treating layer 475 is also formed on a part area of a whole area of the semiconductor layer 474. However, any surface treating layer is not formed on the upper surface of the third semiconductor layer 514. The impurities are doped to the second semiconductor layer 474 and the third semiconductor layer 514.

Thereafter, as shown in FIG. 17H, the inorganic material such as SiOx or SiNx is deposited by CVD method to form the second gate insulating layer 445 having the single layer or the multi layers, and then the metal is deposited thereon and etched to form the second gate electrode 476 and the third gate electrode 516.

Subsequentially, the second interlayer insulating layer 446 having the single layer or the multi layers is formed by depositing the inorganic material, and then the metal is deposited thereon and etched to form the storage electrode 478.

Thereafter, the passivation 447 is formed by depositing the organic material. Subsequently, the first gate insulating layer 442, the first interlayer insulating layer 443, the second buffer layer 444, the second gate insulating layer 445, the second interlayer insulating layer 446, and the passivation layer over the first source region 414b and the first drain region 414c of the first semiconductor layer 414 are etched to from the first contact hole 449a and the second contact hole 449b, and the second gate insulating layer 445, the second interlayer insulating layer 446, and the passivation layer 447 over the second source region 474b and the second drain region 474c of the second semiconductor layer 574 and over the third source region 514b and the third drain region 4514c of the third semiconductor layer 514 are etched to form the third contact hole 449c, the fourth contact hole 449d, the sixth contact hole 449f, and the seventh contact hole 449g. Further, the first interlayer insulating layer 443, the second buffer layer 444, the second gate insulating layer 445, the second interlayer insulating layer 446, and the passivation layer over the first lower blocking metal layer BSM_1 are etched to form the fifth contact hole 449e.

Thereafter, the metal is deposited on the passivation layer 447 and etched to form the first source electrode 422, the first drain electrode 424, the second source electrode 482, the second drain electrode 484, the third source electrode 522, and the third drain electrode 524, and thus the gate thin film transistor GT, the driving thin film transistor DT, and the switching thin film transistor ST are formed.

The first source electrode 422 and the first drain electrode 424 are respectively connected to the first source region 414b and the first drain region 414c of the first semiconductor layer 414 through the first contact hole 449a and the second contact hole 449b. The second source electrode 482 and the second drain electrode 484 are respectively connected to the second source region 474b and the second drain region 474c of the second semiconductor layer 474 through the third contact hole 449c and the fourth contact hole 449d. The third source electrode 522 and the third drain electrode 524 are respectively connected to the third source region 514b and the third drain region 514c of the third semiconductor layer 514 through the sixth contact hole 449f and the seventh contact hole 449g. The second drain electrode 484 is connected to the first lower blocking metal layer BSM_1 through the fifth contact hole 445e.

Subsequentially, the transparent conductive material such as ITO or IZO is deposited and etched in the display area AA of the passivation layer 146 in which the gate thin film transistor GT, the driving thin film transistor DT and the switching thin film transistor ST are disposed to form the first electrode 432. The first electrode 432 is connected to the second drain electrode 484 of the driving thin film transistor DT through the eighth contact hole 449h formed in the passivation layer 447.

Thereafter, the bank layer 452 having the opening is formed on the passivation layer in which the first electrode is formed and then the organic light emitting layer 434 is formed by depositing the organic light emitting material in the opening of the bank layer 452. Subsequently, the metal is deposed on the entire area of the organic light emitting layer 434 in the thickness of several tens of nm by the sputtering method and then etched to form the second electrode 436.

Thereafter, the encapsulating layer 462 is formed over the second electrode 436 by depositing the inorganic material such as SiNx and SiOx and the organic materials such as polyethylene terephthalate, polyethylene naphthalate, polycarbonate, polyimide, polyethylene sulfonate, polyoxymethylene, polyacrylate, etc.

Subsequentially, the adhesive layer (not shown in figure) is coated on the encapsulating layer 462 and the second substrate 470 is disposed on the adhesive layer, and then the adhesive layer is cured to complete the organic light emitting display device.

The features, structures, effects, etc. described in the example of the application are included in at least one example of the application, and are not necessarily limited to one example. Furthermore, the features, structure, effects, etc. exemplified in at least one example of the application can be combined or modified with other examples by a person having general knowledge of the field to which the application belongs. Therefore, the contents related to these combinations and modifications should be interpreted as being included in the scope of the application.

What is claimed is:

1. An organic light emitting display device comprising:
a substrate including a display area and a non-display area;
a driving thin film transistor and a switching thin film transistor in the display area; and
an organic light emitting device in the display area, the organic light emitting device electrically connected to the driving thin film transistor,
wherein the driving thin film transistor includes a first oxide semiconductor layer and the switching thin film transistor includes a second oxide semiconductor layer, and
wherein a surface treating layer including a pattern of protrusions is on a surface of the first oxide semiconductor layer of the driving thin film transistor and the second oxide semiconductor layer of the switching thin film transistor lacks the surface treating layer on a surface of the second oxide semiconductor layer.

2. The organic light emitting display device of claim 1, wherein the first oxide semiconductor layer includes a first channel region, a first source region at a first side of the first channel region, and a first drain region at a second side of the first channel region that is opposite the first side of the first channel region, and the driving thin film transistor further including:
a first gate insulating layer on the first semiconductor layer;
a first gate electrode on the first gate insulating layer;
a passivation layer on the first gate electrode; and
a first source electrode and a first drain electrode on the passivation layer.

3. The organic light emitting display device of claim 2, wherein the second oxide semiconductor layer includes a second channel region, a second source region at a first side of the second channel region, and a second drain region at a second side of the second channel region that is opposite the first side of the second channel region, and the first gate insulating layer is on the second semiconductor layer, the switching thin film transistor further including:
a second gate electrode on the first gate insulating layer, the passivation layer on the second gate electrode; and
a second source electrode and a second drain electrode on the passivation layer.

4. The organic light emitting display device of claim 1, wherein the surface treating layer is on an entire upper surface of the first oxide semiconductor layer.

5. The organic light emitting display device of claim 2, wherein the surface treating layer is on an upper surface of the first channel layer of the first oxide semiconductor layer, but is not on an upper surface layer of the first source region and an upper surface of the first drain region of the first oxide semiconductor layer.

6. The organic light emitting display device of claim 1, wherein the surface treating layer is integral with the first oxide semiconductor layer.

7. The organic light emitting display device of claim 1, further comprising:
a first buffer layer between the substrate and the first oxide semiconductor layer and the second oxide semiconductor layer.

8. The organic light emitting display device of claim 7, wherein an upper surface of the first buffer layer that overlaps the surface treating layer of the first oxide semiconductor layer includes another pattern of protrusions.

9. The organic light emitting display device of claim 2, wherein each of an upper surface of the first gate insulating layer and an upper surface of the first gate electrode that overlap the surface treating layer includes a respective pattern of protrusions.

10. The organic light emitting display device of claim 3, further comprising:
a first lower blocking metal layer between the first oxide semiconductor layer and the substrate; and
a second lower blocking metal layer between the second oxide semiconductor layer and the substrate.

11. The organic light emitting display device of claim 10, further comprising:
a gate driving thin film transistor in the non-display area.

12. The organic light emitting display device of claim 11, wherein the gate driving thin film transistor includes:
a second buffer layer on the substrate, the second buffer layer between the substrate and the first lower blocking metal layer and the second lower blocking metal layer;
a third semiconductor layer on the second buffer layer, the third semiconductor layer in the non-display area;
a second gate insulating layer on the third semiconductor layer;
a third gate electrode on the second gate insulating layer; and
a third source electrode and a third drain electrode on the passivation layer.

13. The organic light emitting display device of claim 12, wherein the third semiconductor includes polycrystalline.

14. The organic light emitting display device of claim 12, wherein the third gate electrode is made of a same material as the first lower blocking metal layer and the second lower blocking metal layer.

15. The organic light emitting display device of claim 12, wherein a thickness of a first portion of the second buffer layer that overlaps the third semiconductor layer is thicker than a second portion of the second buffer layer that is non-overlapping with the third semiconductor layer.

16. The organic light emitting display device of claim 10, wherein the first lower blocking metal layer is connected to one of the first source electrode or the first drain electrode.

17. The organic light emitting display device of claim 16, wherein a first capacitance between the first lower blocking metal layer and the first semiconductor layer is greater than a second capacitance between the first gate electrode and the first semiconductor layer.

18. A display device comprising:
a substrate including a display area;
a first transistor in the display area, the first transistor including a first semiconductor layer with a pattern of protrusions on at least a portion of a surface of the first semiconductor layer;
a second transistor in the display area, the second transistor including a second semiconductor layer that is made of a same material as the first semiconductor layer; and
a light emitting device in the display area, the light emitting device electrically connected to the first transistor,
wherein the second semiconductor layer lacks the pattern of protrusions on any surface of the second semiconductor layer.

19. The display device of claim 18, wherein the first semiconductor layer and the second semiconductor layer are oxide semiconductor layers.

20. The display device of claim 19, wherein the first semiconductor layer with the pattern of protrusions has a S-factor that is greater than a S-factor of the second semiconductor layer.

21. The display device of claim 19, wherein the first semiconductor layer includes a channel region, a source region at a first side of the channel region, and a drain region at a second side of the channel region that is opposite the first side of the channel region, and the pattern of protrusions is on an entire surface of the first semiconductor layer across the source region, the channel region, and the drain region.

22. The display device of claim 19, wherein the first semiconductor layer includes a channel region, a source region at a first side of the channel region, and a drain region at a second side of the channel region that is opposite the first side of the channel region, and the pattern of protrusions is on a surface of the channel region, but is not on a surface of the source region and a surface of the drain region.

23. The display device of claim of claim 18, further comprising:
a first blocking metal layer between the first semiconductor layer and the substrate; and
a second blocking metal layer between the second semiconductor layer and the substrate,
wherein the first blocking metal layer is electrically connected to the first semiconductor layer.

24. The display device of claim 18, wherein the pattern of protrusions is one of a pattern of concave and convex protrusions, a pattern of triangular shaped protrusions, or a pattern of circular protrusions.
